(19) United States
(12) Patent Application Publication
(10) Pub. No.: US 2016/0267989 A1
(43) Pub. Date: Sep. 15, 2016

(54) NONVOLATILE SEMICONDUCTOR MEMORY DEVICE AND OPERATION METHOD THEREOF

(71) Applicant: KABUSHIKI KAISHA TOSHIBA, Minato-ku (JP)

(72) Inventors: Tatsuya OGURA, Yokohama (JP); Yukihiro UTSUNO, Yokohama (JP); Kazuhide SUZUKI, Kawasaki (JP); Koki UENO, Yokohama (JP); Yasuhiro TOMITA, Kamakura (JP); Makoto NAKASHIMA, Yokohama (JP); Kazuhiko MURAKI, Yokohama (JP); Satoshi AOKI, Nagareyama (JP)

(73) Assignee: KABUSHIKI KAISHA TOSHIBA, Minato-ku (JP)

(21) Appl. No.: 14/850,394

(22) Filed: Sep. 10, 2015

Related U.S. Application Data
(60) Provisional application No. 62/131,525, filed on Mar. 11, 2015.

(51) Int. Cl. G11C 16/10; G11C 16/04; G11C 16/34; G11C 16/26; G11C 16/32

(52) U.S. Cl. CPC G11C 16/10; G11C 16/26; G11C 16/32; G11C 16/3459; G11C 16/0483

(57) ABSTRACT

A nonvolatile semiconductor memory device, includes a memory cell array, and a control circuit configured to control voltage applied to the memory cell array. The memory cell array includes: a plurality of first wiring lines extending in a first direction, a plurality of second wiring lines extending in a second direction intersecting with the first direction, and memory cells arranged in respective intersecting portions between the plurality of first wiring lines and the plurality of second wiring lines. The control circuit changes voltages applied to the plurality of first wiring lines and/or times during which voltages are applied to the plurality of first wiring lines independently in each of predetermined spatial periods.

### CROSS REFERENCE TO RELATED APPLICATIONS

This application is based on and claims the benefit of priority from prior U.S. Provisional Patent Application No. 62/131,525, filed on Mar. 11, 2015, the entire contents of which are incorporated herein by reference.

### FIELD

Embodiments described herein relate generally to a nonvolatile semiconductor memory device and an operation method of the nonvolatile semiconductor memory device.

### BACKGROUND

### Description of the Related Art

As a semiconductor memory device that stores data in a nonvolatile manner, a NAND-type flash memory is widely used. Demand for multi-functionalization of an electronic device on which such NAND-type flash memory is mounted requires the NAND-type flash memory to have a large storage capacity. Accordingly, the size of the storage element and the pitch between the wiring lines are required to be scaled down.

### BRIEF DESCRIPTION OF THE DRAWINGS

FIG. 1 is a block diagram illustrating the configuration of a nonvolatile semiconductor memory device according to a first embodiment;

FIG. 2 is an equivalent circuit diagram illustrating the configuration of a memory cell array in FIG. 1;

FIG. 3 is a schematic diagram illustrating the cross-sectional structure of a memory cell MC;

FIG. 4 is a schematic diagram illustrating the cross-sectional structure of a selection transistor SG1 or SG2;

FIG. 5 is a schematic diagram illustrating the cross-sectional structure of a NAND cell unit NU;

FIG. 6 is a plan layout diagram of the memory cell array in FIG. 1;

FIG. 7A is a I-I′ cross-sectional view along a word line WL in FIG. 6;

FIG. 7B is a II-II′ cross-sectional view along a bit line BL in FIG. 6;

FIG. 8 is a schematic diagram illustrating a forming process of the word lines WL by a sidewall transfer process;

FIG. 9 is a schematic diagram illustrating a forming process of the word lines WL by the sidewall transfer process;

FIG. 10 is a schematic diagram illustrating a forming process of the word lines WL by the sidewall transfer process;

FIG. 11 is a schematic diagram illustrating a forming process of the word lines WL by the sidewall transfer process;

FIG. 12 is a schematic diagram illustrating a forming process of the word lines WL by the sidewall transfer process;

FIG. 13 is a schematic diagram illustrating a forming process of the word lines WL by the sidewall transfer process;

FIG. 14 is a schematic diagram illustrating a forming process of the word lines WL by the sidewall transfer process;

FIG. 15 is a schematic diagram illustrating a forming process of the word lines WL by the sidewall transfer process;

FIG. 16 is a schematic diagram illustrating a forming process of the word lines WL by the sidewall transfer process;

FIG. 17 is a schematic diagram illustrating a forming process of the word lines WL by the sidewall transfer process;

FIG. 18 is a schematic diagram describing Single Level Cell in a NAND-type flash memory;

FIG. 19 is a diagram describing an operation method of the nonvolatile semiconductor memory device according to the first embodiment;

FIG. 20 is a diagram describing the operation method of the nonvolatile semiconductor memory device according to the first embodiment;

FIG. 21 is a diagram describing the operation method of the nonvolatile semiconductor memory device according to the first embodiment;

FIG. 22 is a diagram describing an operation method of a nonvolatile semiconductor memory device according to a second embodiment;

FIG. 23 is a diagram describing the operation method of the nonvolatile semiconductor memory device according to the second embodiment;

FIG. 24 is a diagram describing the operation method of the nonvolatile semiconductor memory device according to the second embodiment;

FIG. 25 is a diagram describing an operation method of a nonvolatile semiconductor memory device according to a third embodiment;

FIG. 26 is a diagram describing the operation method of the nonvolatile semiconductor memory device according to the third embodiment;

FIG. 27 is a diagram describing the operation method of the nonvolatile semiconductor memory device according to the third embodiment;

FIG. 28 is a schematic diagram describing Multi Level Cell in a NAND-type flash memory;

FIG. 29 is a schematic diagram describing Multi Level Cell in the NAND-type flash memory;

FIG. 30 is a schematic diagram describing Multi Level Cell in the NAND-type flash memory;

FIG. 31 is a diagram describing an operation method of a nonvolatile semiconductor memory device according to a fourth embodiment;

FIG. 32 is a diagram describing an operation method of a nonvolatile semiconductor memory device according to a fifth embodiment; and

FIG. 33 is a diagram describing an operation method of a nonvolatile semiconductor memory device according to a sixth embodiment.

### DETAILED DESCRIPTION

A semiconductor memory device according to one embodiment includes a memory cell array and a control circuit, which controls voltage applied to the memory cell array. The memory cell array includes first wiring lines, second wiring lines intersecting with the first wiring lines, and memory cells arranged in the intersecting portions of the first and second wiring lines. The control circuit repeats a write pulse application operation and a verify read operation in a write operation from the memory cell. The write pulse application operation causes application of a write pulse voltage to the memory cell. The verify read operation causes application of a first voltage to the memory cell to determine whether the write operation is completed. The control circuit applies a second voltage to the memory cell in a read operation from the memory cell. The second voltage has a voltage value larger than that of the first voltage.

The following describes embodiments of the nonvolatile semiconductor memory device and the operation method of the nonvolatile semiconductor memory device with reference to the drawings.

### First Embodiment

### Overall Configuration

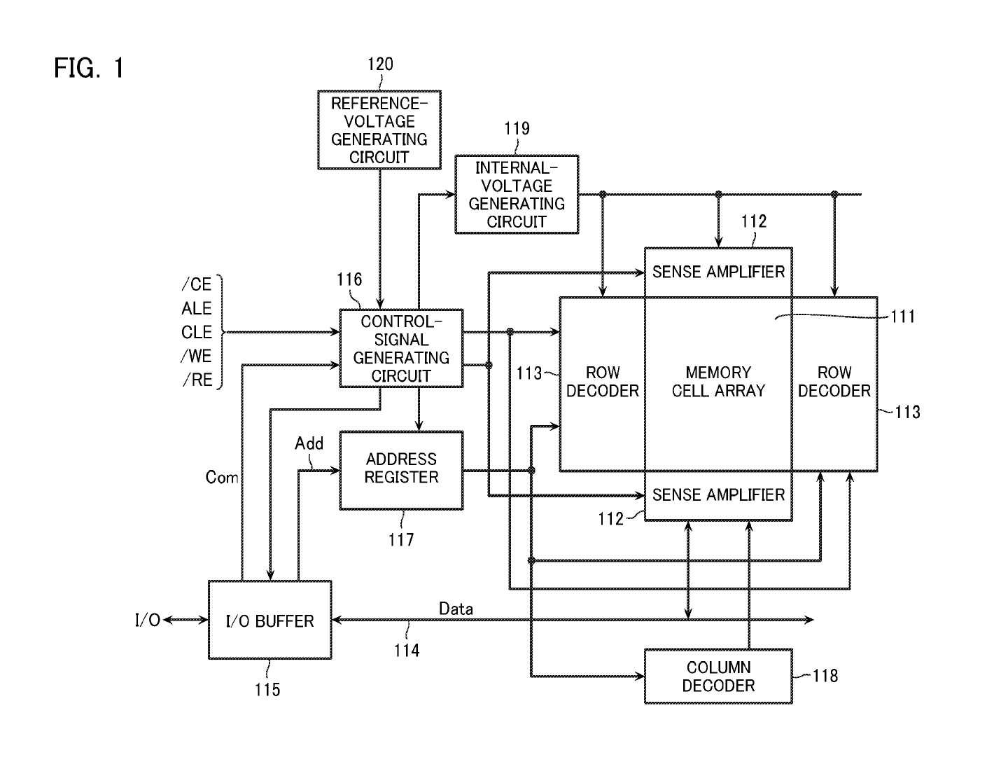

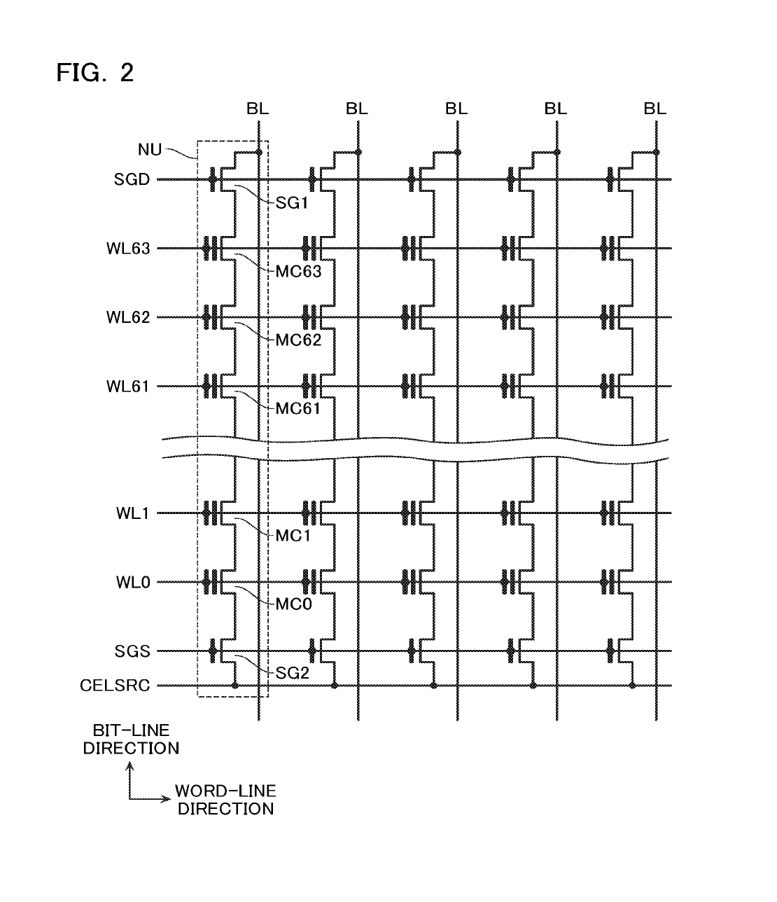

Firstly, a description will be given of the configuration of a nonvolatile semiconductor memory device according to a first embodiment with reference to FIG. 1 and FIG. 2. FIG. 1 is a block diagram illustrating the configuration of the nonvolatile semiconductor memory device (NAND-type flash memory) according to the first embodiment. FIG. 2 is an equivalent circuit diagram illustrating the configuration of a memory cell array 111. Here, in FIG. 2, the direction in which word lines WL extend is referred to as a word-line direction, and the direction in which bit lines BL extend is referred to as a bit-line direction.

The nonvolatile semiconductor memory device according to the first embodiment includes, as illustrated in FIG. 1, the memory cell array 111, sense amplifiers 112, row decoders 113, a data line 114, an I/O buffer 115, a control-signal generating circuit 116, an address register 117, a column decoder 118, an internal-voltage generating circuit 119, and a reference-voltage generating circuit 120.

### (Memory Cell Array 111)

As illustrated in FIG. 2, the memory cell array 111 is constituted by arraying NAND cell units NU in a matrix. Each of the respective NAND cell units NU includes, for example, 64 nonvolatile memory cells MC0 to MC63 (a memory string), which are series-coupled together and electrically rewritable, and selection transistors SG1 and SG2, which are used for coupling both respective ends of the memory string to the bit line BL and a common source line CELSRC.

The control gates of the memory cells M0 to M63 within the NAND cell unit NU are coupled to different word lines WL0 to WL63. The gates of the selection transistors SG1 and SG2 are coupled to the respective selection gate lines SGD and SGS. The collection of the NAND cell units NU sharing one word line WL constitutes a block BLK as a unit of data erasure. While not illustrated, a plurality of the blocks BLK are arrayed in the bit-line direction.

The respective bit lines BL are coupled to the sense amplifiers 112 illustrated in FIG. 1. A plurality of the memory cells MC coupled in common to one word line WL constitute one page or a plurality of pages.

As illustrated in FIG. 1, the sense amplifiers 112 are arranged in the bit-line direction of the memory cell array 111, and are coupled to the bit line BL to read data in units of pages and double as a data latch that holds write data of one page. That is, read and write are performed in units of pages. The sense amplifier 112 includes a data cache, which temporarily holds input-output data, and a column selection gate circuit (not illustrated), which selects a column.

As illustrated in FIG. 1, the row decoders 113 are arranged in the word-line direction of the memory cell array 111 and selectively drive the word lines WL and the selection gate lines SGD and SGS in accordance with row addresses. This row decoder 113 includes a word-line driver and a selection-gate-line driver. The column decoder 118, which controls the column selection gate circuit inside the sense amplifier 112, is disposed together with the sense amplifier 112. The row decoder 113, the column decoder 118, and the sense amplifier 112 constitute a read/write circuit for reading and writing data of the memory cell array 111.

Between an external input/output port I/O and the sense amplifier 112, data is forwarded by the input/output buffer 115 and the data line 114. That is, the page data read out by the sense amplifier 112 is output to the data line 114 and is output to the input/output port I/O via the input/output buffer 115. The write data supplied from the input/output port I/O is loaded to the sense amplifier 112 via the input/output buffer 115.

Address data Add supplied from the input/output port I/O is supplied to the row decoder 113 and the column decoder 118 via the address register 117. Command data Com supplied from the input/output port I/O is decoded and then set to the control-signal generating circuit 116.

Respective external control signals including a chip enable signal /CE, an address latch enable signal ALE, a command latch enable signal CLE, a write enable signal /WE, and a read enable signal /RE are supplied to the control-signal generating circuit 116. The control-signal generating circuit 116 performs operation controls for general memory operations based on the command Com and the external control signals and additionally controls the internal-voltage generating circuit 119 to generate various internal voltages required for data read, write, and erasure. The control-signal generating circuit 116 receives a reference voltage from the reference-voltage generating circuit 120. The control-signal generating circuit 116 performs writing from a selected memory cell MC at the source line SL side, and controls a read operation.

### (Memory Cell MC and Selection Transistors SG1 and SG2)

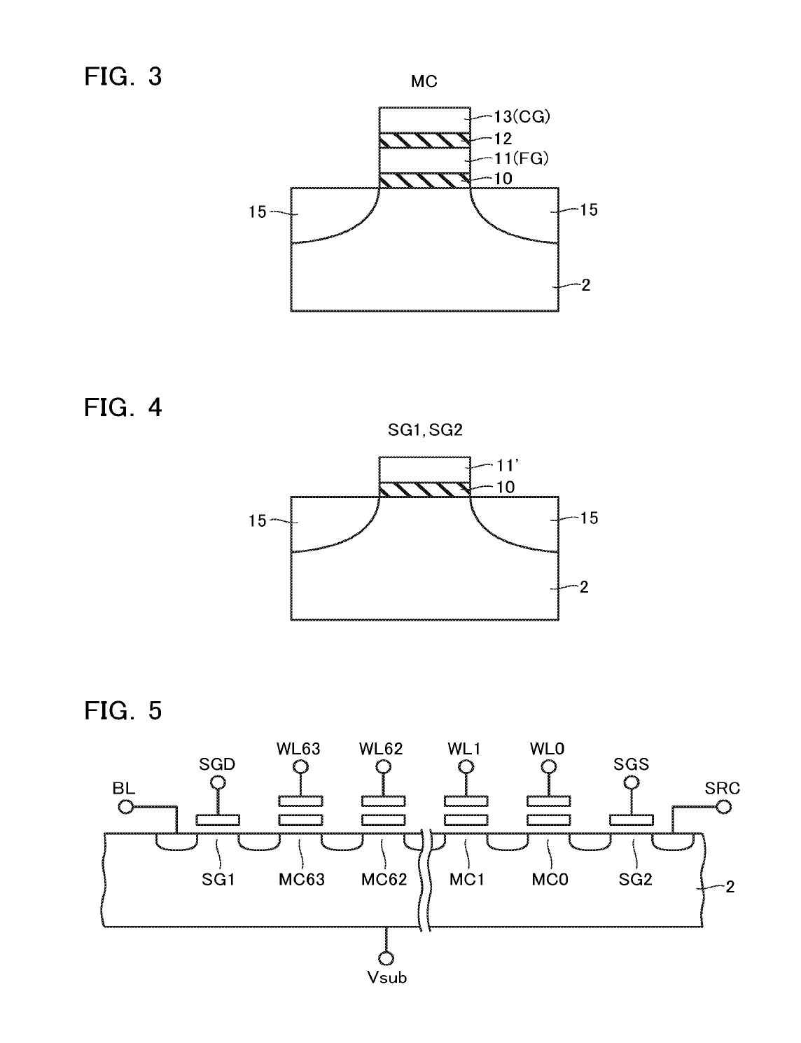

FIG. 3 and FIG. 4 illustrate schematic cross-sectional views of the memory cell MC and the selection transistors SG1 and SG2. In a p-type well 2 formed on a semiconductor substrate (not illustrated), n-type source/drain diffusion layers 15 are formed. The region sandwiched between the two diffusion layers 15 in the p-type well 2 functions as a channel region of a MOSFET that constitutes the memory cell MC.

Additionally, in the p-type well 2, a floating gate (FG) 11 is formed via a gate insulating film 10. The floating gate 11 is configured to hold electric charges inside, and the threshold voltage of the memory cell MC is determined by the electric charge amount. Here, as a charge storage film instead of the floating gate, a charge trap film may be used. On this floating gate 11, a control gate (CG) 13 is formed via an intergate insulating film 12.

The selection transistors SG1 and SG2 each include the p-type well 2, which is formed on the semiconductor substrate (not illustrated), and the n-type source/drain diffusion layers 15, which are formed on the surface of this p-type well 2. Here, instead of the diffusion layer, a source and a drain using a fringing field may be used. On the p-type well 2, a control gate 11′ is formed via the gate insulating film 10.

### (NAND Cell Unit NU)

FIG. 5 illustrates a schematic cross-sectional view of one NAND cell unit NU inside the memory cell array 111. In this example, one NAND cell unit NU is constituted such that 64 memory cells MC having the configurations illustrated in FIG. 3 and the selection transistors SG1 and SG2 having the configurations in FIG. 4 are series-coupled together.

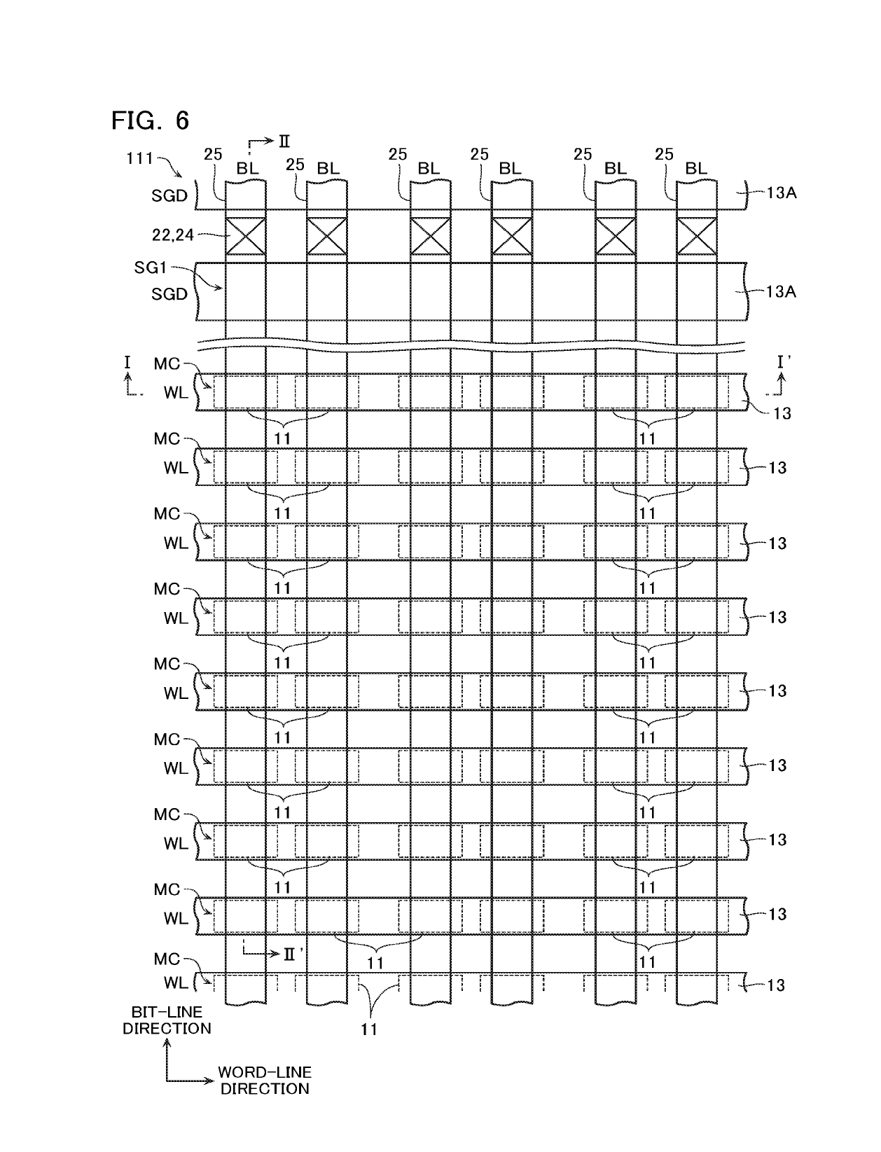

FIG. 6 illustrates a planar layout of the memory cell array 111. The word lines (WL) 13 and the bit lines (BL) 25 are arranged to intersect with one another. In respective intersecting portions 11 between these lines, the memory cells MC are formed. A plurality of the memory cells MC arranged in the bit-line direction are series-coupled together so as to constitute the NAND cell unit NU as described later. The NAND cell unit NU has one end coupled to the bit line BL via the selection gate transistor SG1.

The gate of the selection gate transistor SG1 is continuously arranged as the selection gate line (SGD) 13A parallel to the word lines WL. While the illustration is omitted in FIG. 6, the NAND cell unit NU has the other end coupled to the source line CELSRC via the selection gate transistor SG2.

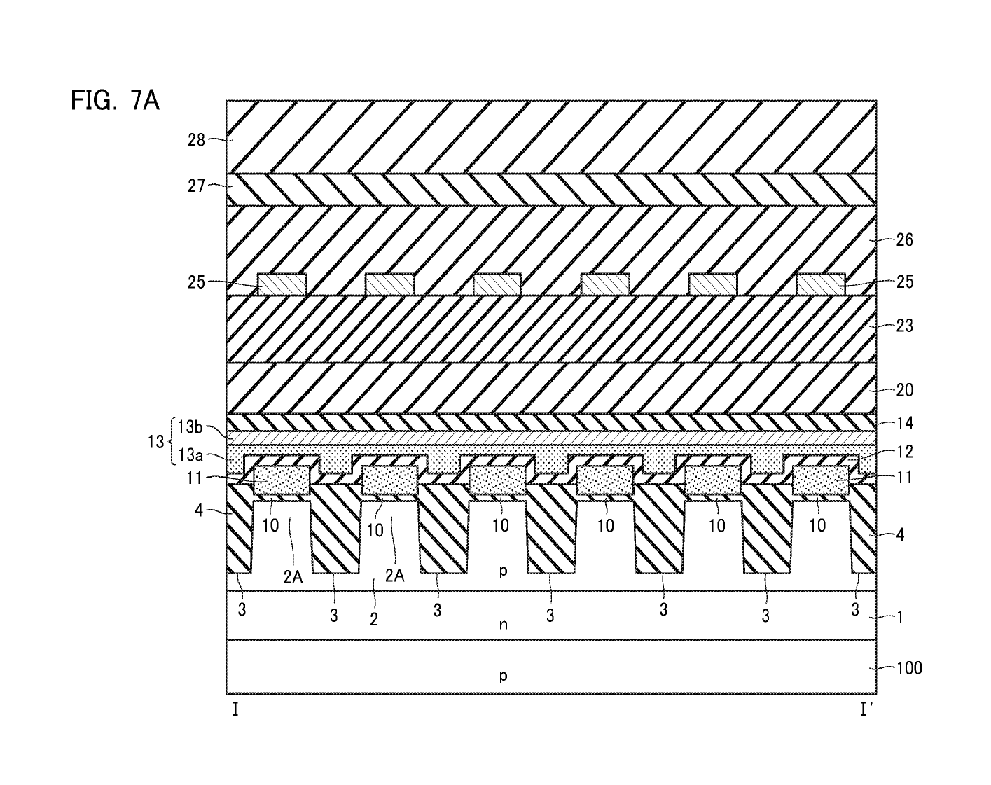

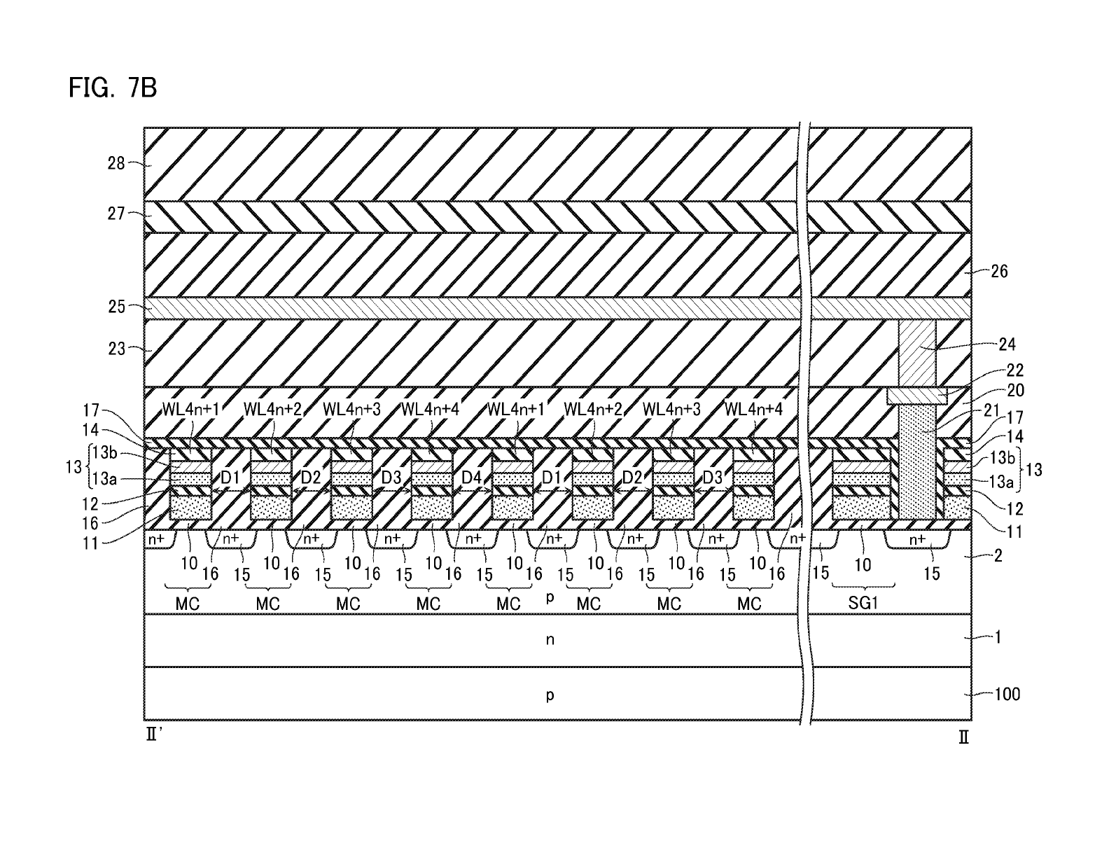

FIG. 7A is a I-I′ cross-sectional view along the word line WL in FIG. 6. FIG. 7B is a II-II′ cross-sectional view similarly along the bit line BL. In a cell array region on a p-type silicon substrate 100, an n-type well 1 and the p-type well 2 are formed. In this p-type well 2, trenches 3 are formed at predetermined intervals. In these trenches 3, element isolation insulating films 4 are formed. In the p-type well 2 sandwiched between these element isolation insulating films 4, the memory cell MC is formed. That is, the p-type well 2 sandwiched between the element isolation insulating films 4 functions as an element formation region 2A where the memory cell MC and similar member are formed and that extends having the longitudinal direction in the bit-line direction.

On the surface of the element formation region 2A, the floating gate 11 formed of a polysilicon film is formed via the tunnel oxide film 10. On this floating gate 11, the control gate 13 is formed via the intergate insulating film 12 (such as an ONO film). The control gate 13 can be formed from laminated films of a polysilicon film 13a and a tungsten (W) film 13b or formed of nickel silicide (NiSix).

The control gate 13 is continuously patterned having the longitudinal direction in the word-line direction as the word line WL.

As illustrated in FIG. 7B, the word lines WL form a pattern where the word lines WL having substantially identical cross-sectional shapes are repeated every four lines in an order from 4n+1, 4n+2, 4n+3, 4n+4, 4n+1, 4n+2, 4n+3, 4n+4, . . . from the left side of the drawing. Accordingly, a distance D1 between 4n+1 and 4n+2, a distance D2 between 4n+2 and 4n+3, a distance D3 between 4n+3 and 4n+4, and a distance D4 between 4n+4 and 4n+1 have mutually different dimensions. The reason for above will be described later.

The control gate 13 and the floating gate 11 are simultaneously patterned using a silicon nitride film (SiN film) 14 as a mask. Ion implantation is performed using this film as a mask so as to form the source/drain diffusion layer 15. The diffusion layer 15 is shared by the adjacent memory cells MC so as to form a NAND string where a plurality of the memory cells MC are series-coupled together. The selection gate transistors are coupled to both ends of this NAND string, so as to form the NAND cell unit NU. The portions between the respective gate electrodes of the memory cell array 111 thus formed are filled with an interlayer insulating film 16 to be flat. Further, to cover the memory cell array 111, a SiN film 17 is deposited.

The top of the memory cell array 111 is covered with an interlayer insulating film 20. In this interlayer insulating film 20, a contact plug 21 and a tungsten (W) wiring line 22 as a first layer metal are implanted. Further, an interlayer insulating film 23 is laminated. In this interlayer insulating film 23, a contact plug 24 is implanted. On this film, the bit line (BL) 25 is formed using an Al film as a second layer metal. FIG. 7B illustrates the contact portion at the bit line side alone, and the W wiring line 22 is a relay wiring line for the bit line. At the source line side, a source wiring line is formed by the film identical to the W wiring line 22.

On the bit line 25, a silicon oxide film 26, a SiN film 27 by plasma CVD, and a polyimide film 28 are deposited as a passivation film.

### [Method of Manufacturing NAND-Type Flash Memory]

A NAND-type flash memory is manufactured using, for example, what is called a sidewall transfer process. In this process, a resist is patterned by a minimum processing dimension F and undergoes a slimming process to be further thinned. Subsequently, a hard mask is processed using the resist as a mask, and a sidewall mask is deposited on the sidewalls of the hard mask. Subsequently, an etching process, which removes the hard mask alone and leaves the sidewall mask, is performed. This remaining sidewall mask is used to etch the material film as the lower layer of the sidewall mask. This allows forming various wiring lines and similar member with widths and pitches smaller than the minimum processing dimension F (a single spacer process).

In the manufacture of the latest NAND-type flash memory, to respond to a request for further scaling down, a double spacer process (Double Sidewall Assisted Patterning: DSAP) has been used. In the double spacer process, a second sidewall mask is additionally formed on the sidewalls of the above-described sidewall mask (first sidewall mask). Then, the first sidewall mask is removed alone and the remaining second sidewall mask is used to etch the lower layer of the second sidewall mask.

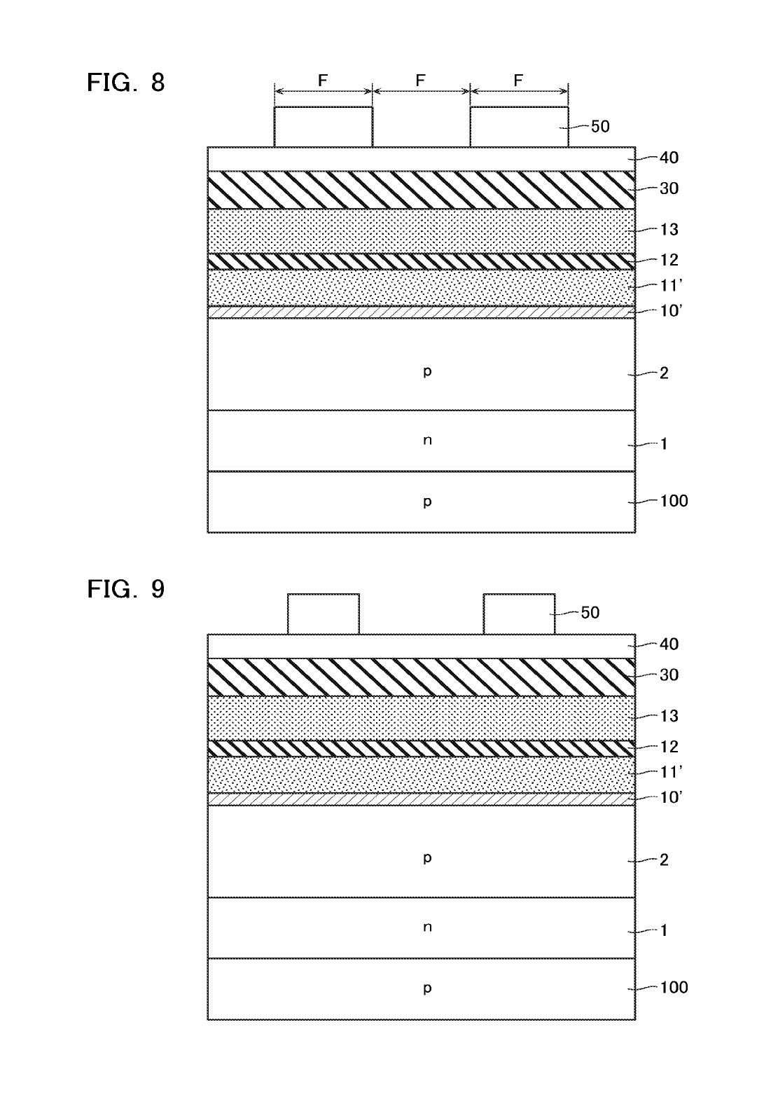

In this embodiment, the double spacer process is used when the word lines WL, the bit lines BL, the trenches 3, and similar member are formed. Here, a description will be given of the procedure in the case where the word lines WL are formed using the double spacer process with reference to FIG. 8 to FIG. 17. Because the bit lines BL, the trenches 3, and similar member can be formed by a similar method, the descriptions of these members are omitted.

Firstly, as illustrated in FIG. 8, on the p-type silicon substrate 100, the n-type well 1 and the p-type well 2 are formed in this order. On top of that, a silicon oxide film 10′ as the material of the tunnel oxide film 10, a polysilicon film 11′ as the material of the floating gate 11, the intergate insulating film 12, and the control gate 13 are formed in this order. Furthermore, a first hard mask 30 is deposited to be used for etching the silicon oxide film 10′, the polysilicon film 11′, the intergate insulating film 12, and the control gate 13.

The first hard mask 30 can be formed of, as one example, a silicon nitride film (SiN), a BSG film, a TEOS film, or a composite film by depositing a BSG film and similar film. This is only one example, and masks in various forms (such as the number of layers, the thicknesses of the respective layers, the materials) can be obtained taking into consideration etching conditions, mask materials, and similar parameter.

Further on top of this first hard mask 30, a second hard mask 40, which has a composition different from that of the first hard mask 30, is formed. The second hard mask 40 can be formed from, for example, amorphous silicon.

Subsequently, an anti-reflection film (not illustrated) and a resist are applied over the entire surface of this second hard mask 40. Then, the resist is developed to form a line-and-space pattern with the minimum processing dimension F (the resolution limit) by photolithography, so as to form a resist 50 having a line-and-space pattern shape.

Subsequently, as illustrated in FIG. 9, the anti-reflection film (not illustrated) is etched by isotropic etching and, simultaneously, the resist 50 undergoes the slimming process so as to thin the resist 50 to have a width equal to or less than the minimum processing dimension F (the resolution limit) of photolithography. For example, in the portion of the memory cell array, the resist 50 is processed to have a line width of approximately ½F and a space width of approximately 3/2F.

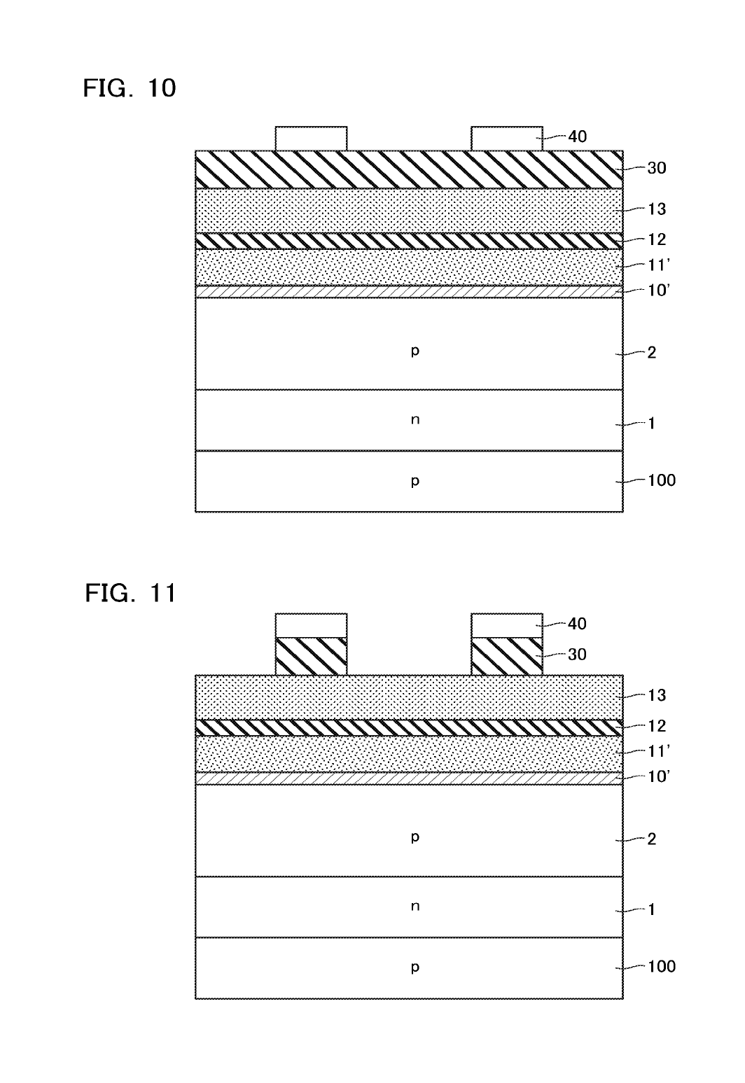

Subsequently, as illustrated in FIG. 10, the second hard mask 40 is etched by anisotropic etching using the resist 50 processed by the slimming process as a mask. After the etching, the resist 50 is peeled.

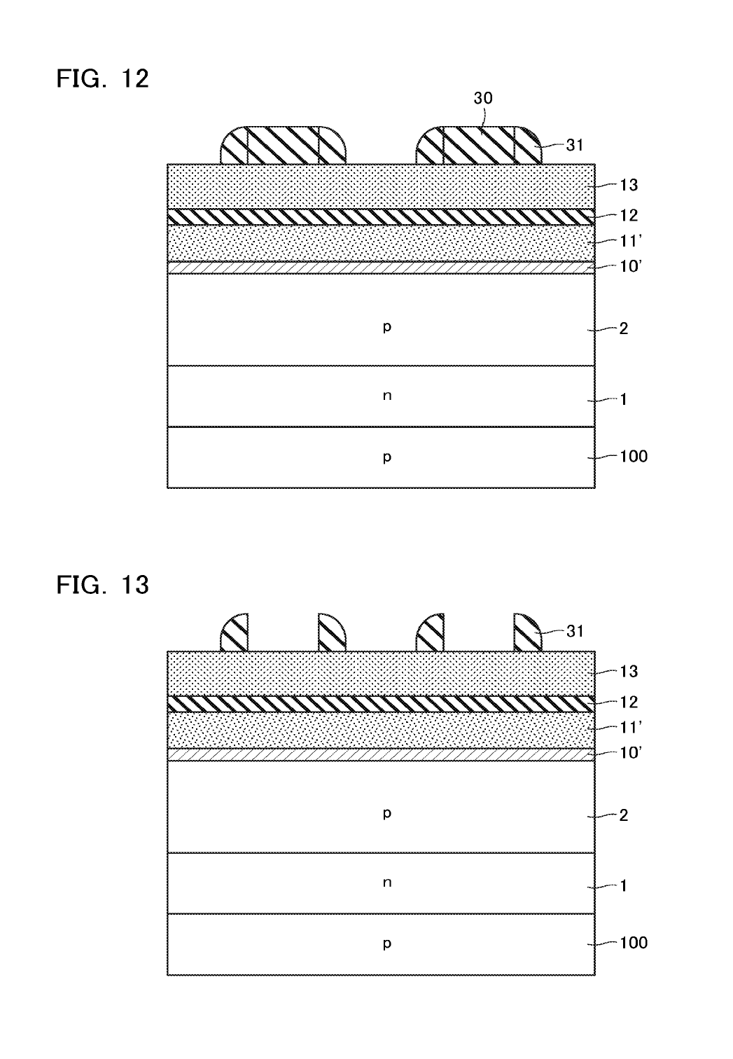

Subsequently, as illustrated in FIG. 11, the first hard mask 30 is etched by anisotropic etching using the second hard mask 40 as a mask. Then, the second hard mask 40 is peeled by isotropic etching. Subsequently, a silicon nitride film is deposited on the entire surface on the first hard mask 30 by a CVD method. Then, as illustrated in FIG. 12, anisotropic etching is performed such that the silicon nitride film is etched to remain only on the sidewalls of the first hard mask 30. Then, as illustrated in FIG. 13, wet etching is performed such that the hard mask 30 is removed and the silicon nitride film on the sidewalls is left as a first sidewall film 31.

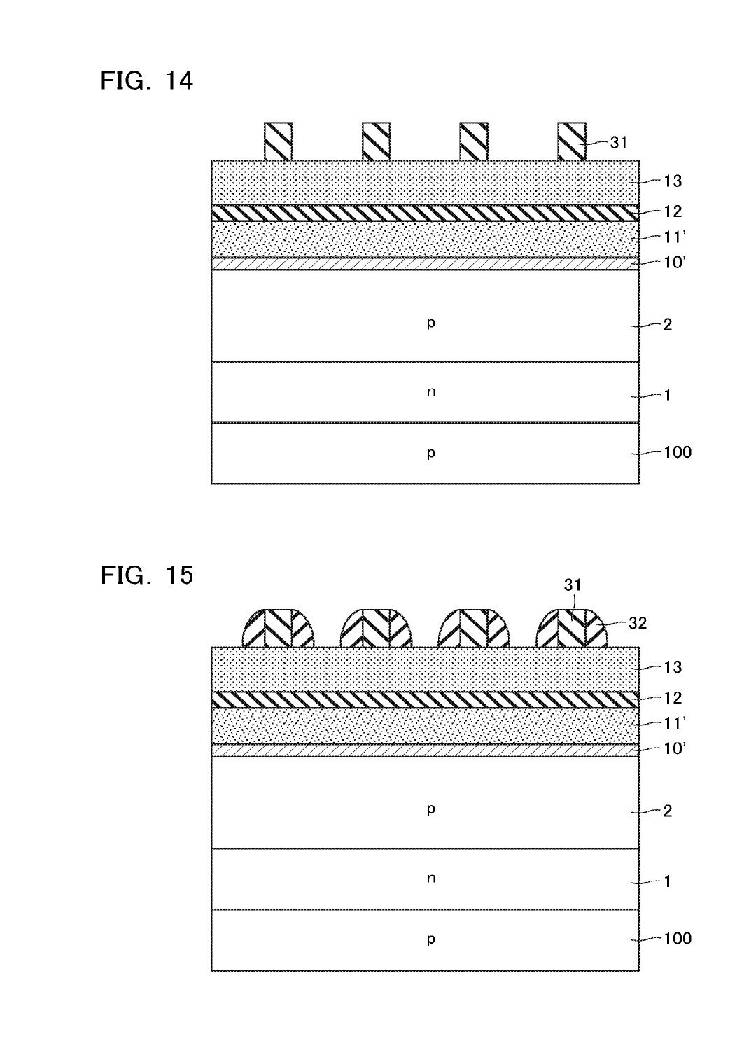

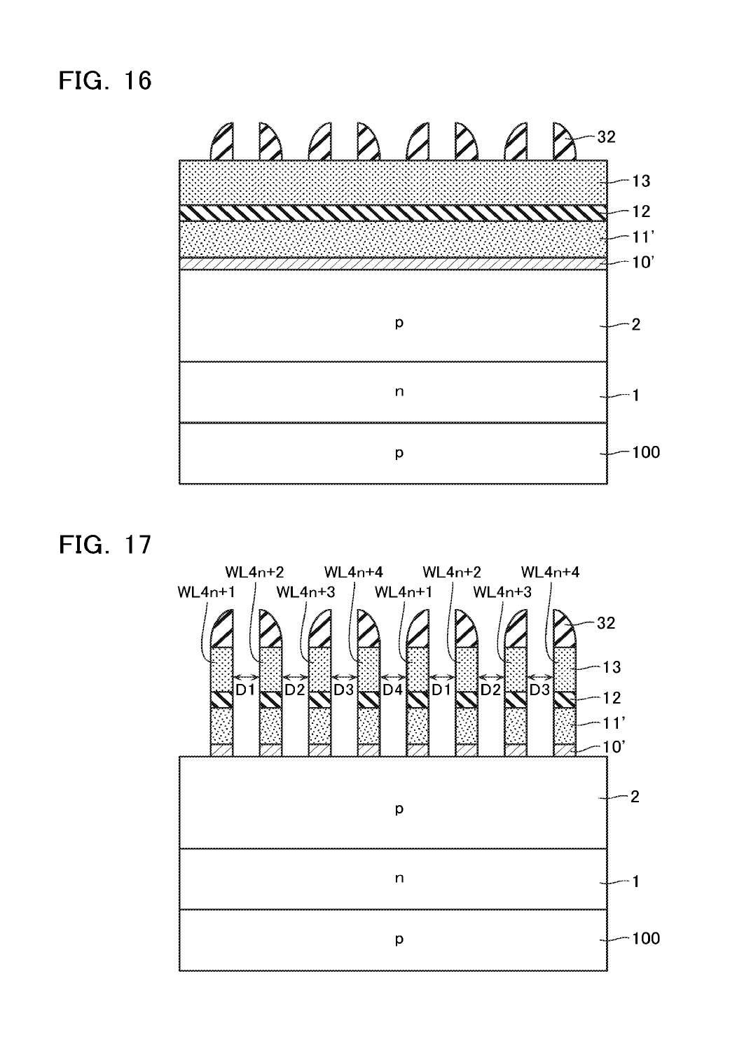

Furthermore, anisotropic etching is performed to shape the first sidewall film 31 by the slimming process as illustrated in FIG. 14. Then, a silicon nitride film to be a second sidewall film 32 is deposited on the entire surface on the first sidewall film 31 by a CVD method. Then, as illustrated in FIG. 15, anisotropic etching is performed such that the silicon nitride film is etched to remain only on the first sidewall film 31. Further, as illustrated in FIG. 16, wet etching is performed such that the first sidewall film 31 is removed and the silicon nitride film on the sidewalls is left as the second sidewall film 32.

This etching using the second sidewall film 32 alone as the mask causes, as illustrated in FIG. 17, formation of a plurality of the word lines WL having the widths and the distances equal to or less than the minimum processing dimension F.

However, in the memory cell array scaled down by a manufacturing method using this double spacer process, the variation of the word line WL becomes large compared with a memory cell array manufactured by a typical single spacer process.

That is, in the typical single spacer process, an even-odd variation occurs due to the patterning process using one sidewall film. In the even-odd variation, the even-numbered word lines WL and the odd-numbered word lines WL have mutually different cross-sectional shapes. In contrast, in the double spacer process, not only the first sidewall film but also the second sidewall film is used. Accordingly, four types of variations, which are an even-even variation, the even-odd variation, an odd-even variation, and an odd-odd variation, occur in the word lines WL. Accordingly, as illustrated in FIG. 7B and FIG. 17, the word lines WL form a pattern where substantially identical cross-sectional shapes appear every four lines in an order from 4n+1, 4n+2, 4n+3, 4n+4, 4n+1, 4n+2, 4n+3, 4n+4, . . . along the bit-line direction. Accordingly, the distance D1 between 4n+1 and 4n+2, the distance D2 between 4n+2 and 4n+3, the distance D3 between 4n+3 and 4n+4, and the distance D4 between 4n+4 and 4n+1 have mutually different dimensions.

As just described, application of the double spacer process when the word lines WL are formed increases the variation of the word line WL compared with the single spacer process and additionally increases the influence of an inter-cell interference effect. Accordingly, there arises a concern about the influences of: the reduction in reliability of the memory cell; and the deterioration in performance of the memory cell. The solution for these problems will be described later.

### [Operation of NAND-Type Flash Memory (Single Level Cell)]

The following specifically describes the operation of the NAND-type flash memory according to this embodiment.

Data is usually written after the batch erase of the data in a block in units of pages. To briefly describe, corresponding to write data of “0” or “1,” “L” (=Vss) or “H” (=Vdd) is supplied to the bit line BL, and this write data is transferred to the channels of the respective NAND cell units. These write data are preliminary supplied to the sense amplifiers 112 via the data cache.

Then, a write voltage (program voltage) Vpgm is supplied to a selected word line, and a read voltage Vpass is supplied to a non-selected word line at least on the bit line side with respect to the selected word line. The read voltage Vpass turns on a cell irrespective of the data. Accordingly, in a “0” write cell along the selected word line whose channel is set to Vss, electrons are injected into the floating gate and “0” data with a high threshold is written. In a “1” write cell (write inhibit cell) along the selected word line, the channel is precharged to Vdd-Vth in a floating state and thus is boosted by capacitive coupling. Accordingly, electron injection does not occur in the floating gate. Here, Vth is a threshold of the selection gate transistor SG1. Also in the remaining non-selected cell, the electric potential of the channel is increased and thus the write does not occur.

To efficiently increase the channel potential in the non-selected cell, a self-boost method is used. This method includes an ordinary self-boost method, which supplies 0 V to the non-selected word line adjacent to the source line side of the selected word line, and a local self-boost method, which supplies 0 V to the non-selected word lines on both sides of the selected word line. However, their detailed descriptions are omitted.

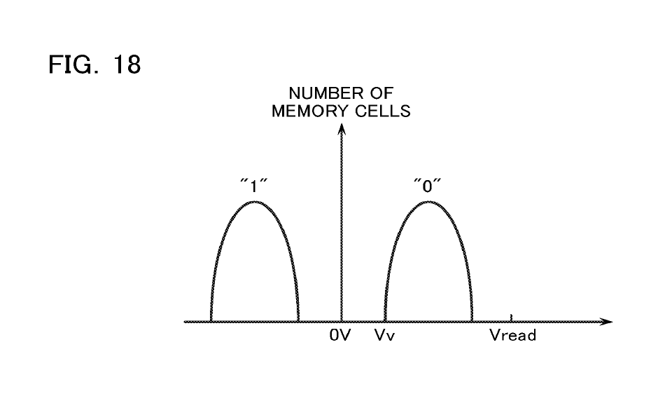

In the case of two-valued data, the data threshold distributions of the memory cell is as illustrated in FIG. 18. Data “1” (erased state) is a state (usually, a state of a negative threshold) of a low threshold, and data “0” is a state (usually, a state of a positive threshold) of a high threshold. To set these data distributions within a predetermined threshold range, in a data write operation, application of a write pulse voltage and a verify operation are repeated. The verify operation confirms a write state.

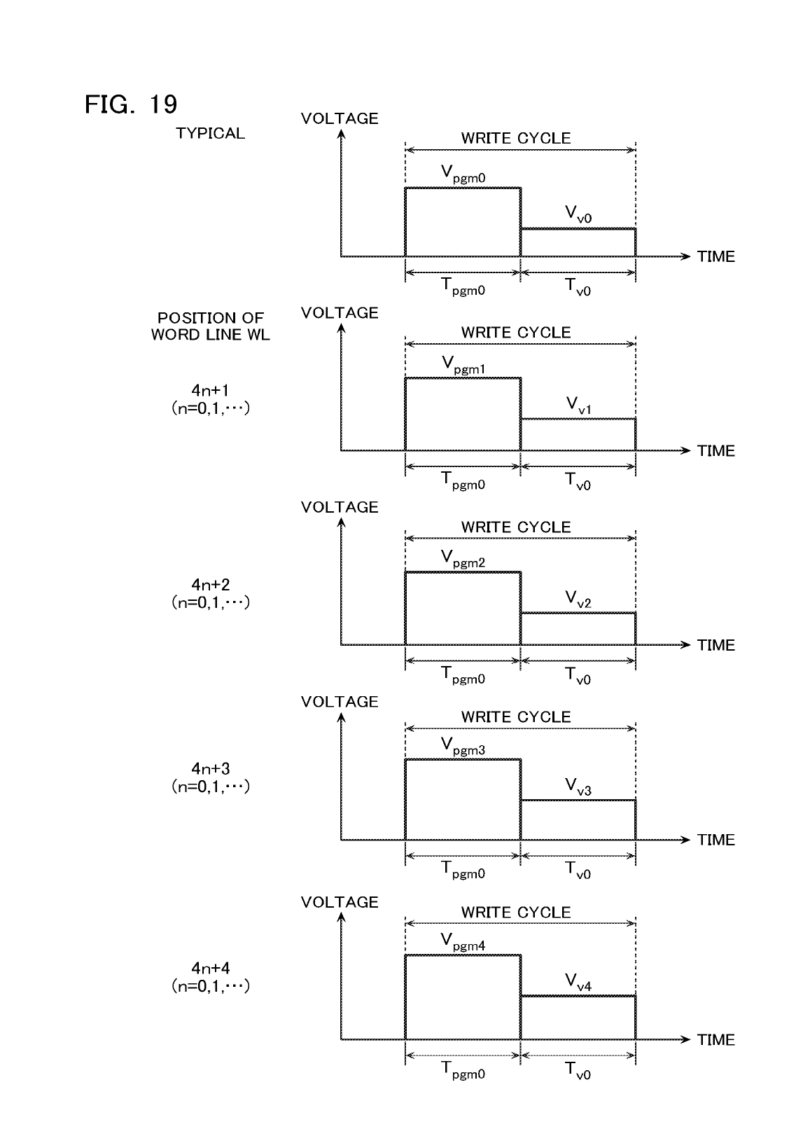

FIG. 19 illustrates this write cycle. The write cycle includes an application operation of the write voltage Vpgm and a verify read operation, which supplies a verify voltage Vv for confirming write data. The write cycle is repeated until data write for one page is completed. Here, FIG. 19 illustrates the write cycle at the initial first time alone. The verify voltage Vv is a “0” data discrimination threshold illustrated in FIG. 18, and is supplied to the selected word line as the read voltage.

In a normal data read, the threshold determination of “0” and “1” illustrated in FIG. 18 is performed. Accordingly, 0 V is supplied to the selected word line and the read voltage Vread, which turns on a cell irrespective of the data of the cell, is supplied to the non-selected word line within the block, so as to detect the presence or absence of discharge of the bit line in the selected cell. In write verify read, to determine whether the “0” data is written, the verify voltage Vv illustrated in FIG. 18 is supplied to the selected word line. The other operations are basically similar to those in the normal read.

Here, as described above, as illustrated in FIG. 7B and FIG. 17, the word lines WL form a pattern where substantially identical cross-sectional shapes appear every four lines in an order from 4n+1, 4n+2, 4n+3, 4n+4, 4n+1, 4n+2, 4n+3, 4n+4, . . . along the bit-line direction. Accordingly, the distance D1 between 4n+1 and 4n+2, the distance D2 between 4n+2 and 4n+3, the distance D3 between 4n+3 and 4n+4, and the distance D4 between 4n+4 and 4n+1 have mutually different dimensions. Therefore, the word lines WL are affected by dimension variation during write and read operations, and the voltage applied to the control gate, and the voltages applied to the adjacent memory cell are changed. In particular, the word lines WL are considerably affected by the adjacent read voltage Vread due to the dimension variation during a read operation, and the influence in its own cell increases during verification.

### Operation According to this Embodiment

Therefore, in this embodiment, different program voltages, verify voltages, and read voltages are applied for different groups of the four word lines WL. Specifically, as illustrated in FIG. 19, the program voltages are set as: Vpgm1 for the word line WL in the (4n+1)-th (n=0, 1, . . . ) position; Vpgm2 for the word line WL in the (4n+2)-th (n=0, 1, . . . ) position; Vpgm3 for the word line WL in the (4n+3)-th (n=0, 1, . . . ) position; and Vpgm4 for the wordline WL in the (4n+4)-th (n=0, 1, . . . ) position, from a given reference position. The values of Vpgm1 to Vpgm4 are determined taking into consideration the dimensions of the word lines WL. For example, when a typically applied program voltage is Vpgm0, Vpgm1 to Vpgm4 are set to be lower than Vpgm0 in the case where the width dimensions of the word lines WL are larger than the typical value. In contrast, in the case where the width dimensions of the word lines WL are smaller than the typical value, Vpgm1 to Vpgm4 are set to be higher than Vpgm0. However, the difference (ΔVpgm1) between Vpgm1 and Vpgm0, the difference (ΔVpgm2) between Vpgm2 and Vpgm0, the difference (ΔVpgm3) between Vpgm3 and Vpgm0, and the difference (ΔVpgm4) between Vpgm4 and Vpgm0 are all within 5% of the value of Vpgm0.

Similarly, as illustrated in FIG. 19, the verify voltages are set as: Vv1 for the word line WL in the (4n+1)-th (n=0, 1, . . . ) position; Vv2 for the word line WL in the (4n+2)-th (n=0, 1, . . . ) position; Vv3 for the word line WL in the (4n+3)-th (n=0, 1, . . . ) position; and Vv4 for the word line WL in the (4n+4)-th (n=0, 1, . . . ) position, from a given reference position. The values of Vv1 to Vv4 are also determined taking into consideration the dimensions of the word lines WL. For example, when a typically applied verify voltage is Vv0, Vv1 to Vv4 are set to be lower than Vv0 in the case where the width dimensions of the word lines WL are larger than the typical value. In contrast, in the case where the width dimensions of the word lines WL are smaller than the typical value, Vv1 to Vv4 are set to be higher than Vv0. However, the difference (ΔVv1) between Vv1 and Vv0, the difference (ΔVv2) between Vv2 and Vv0, the difference (ΔVv3) between Vv3 and Vv0, and the difference (ΔVv4) between Vv4 and Vv0 are all within 10% of the value of Vv0.

In this embodiment, the application times (pulse widths) of the program voltages Vpgm1 to Vpgm4 and the application times (pulse widths) of the verify voltages Vv1 to Vv4 are respectively set as Tpgm0 and Tv0 as in a typical manner.

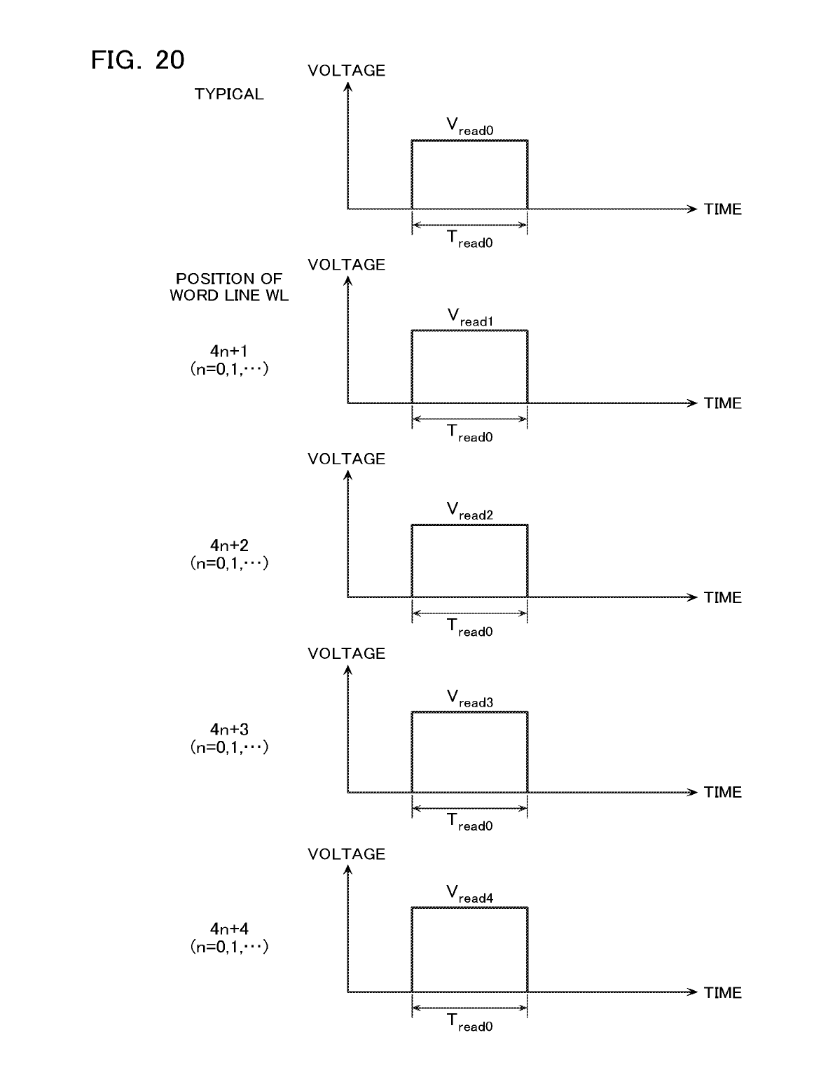

As illustrated in FIG. 20, also regarding the read voltage Vread, Vread1 is applied to the word line WL in the (4n+1)-th (n=0, 1, . . . ) position, Vread2 is applied to the word line WL in the (4n+2)-th (n=0, 1, . . . ) position, Vread3 is applied to the word line WL in the (4n+3)-th (n=0, 1, . . . ) position, and Vread4 is applied to the word line WL in the (4n+4)-th (n=0, 1, . . . ) position, from a given reference position. The values of Vread1 to Vread4 are also determined taking into consideration the dimensions of the word lines WL. For example, when a typically applied read voltage is Vread0, Vread1 to Vread4 are set to be lower than Vread0 in the case where the width dimensions of the word lines WL are larger than the typical value. In contrast, in the case where the width dimensions of the word lines WL are smaller than the typical value, Vread1 to Vread4 are set to be higher than Vread0. However, the read voltage Vread is considerably affected by the adjacent read voltage during the read operation. Accordingly, in the case where the width dimensions of the word lines WL are changed by several nm and thus the distances to the adjacent word lines WL are changed by several nm, the difference (ΔVread1) between Vread1 and Vread0, the difference (ΔVread2) between Vread2 and Vread0, the difference (ΔVread3) between Vread3 and Vread0, and the difference (ΔVread4) between Vread4 and Vread0 are all about 20 mV to 300 mV. Because Vread0 is ordinarily around 7 V, ΔVread1, ΔVread2, ΔVread3, and ΔVread4 are all within 4% of the value of Vread0.

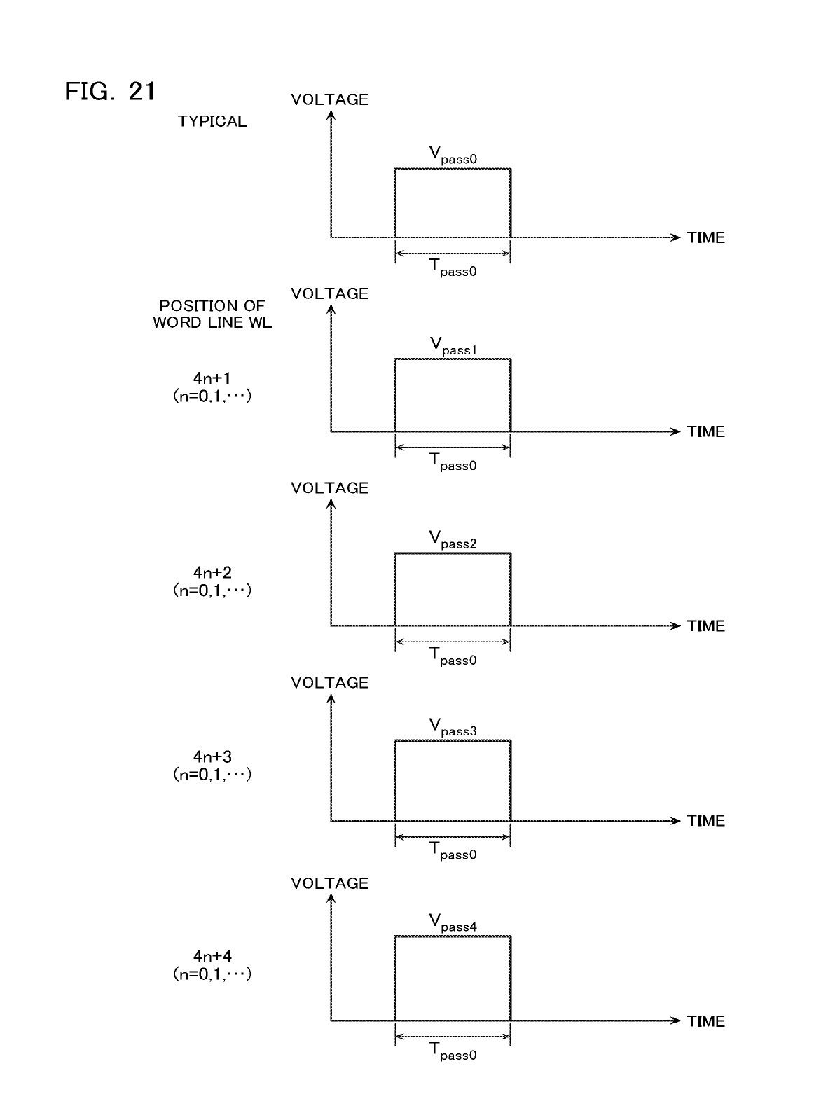

As illustrated in FIG. 21, also regarding the pass voltage Vpass applied to the adjacent word lines WL during a program operation, Vpass1 is applied to the word line WL in the (4n+1)-th (n=0, 1, . . . ) position, Vpass2 is applied to the word line WL in the (4n+2)-th (n=0, 1, . . . ) position, Vpass3 is applied to the word line WL in the (4n+3)-th (n=0, 1, . . . ) position, and Vpass4 is applied to the word line WL in the (4n+4)-th (n=0, 1, . . . ) position, from a given reference position. The values of Vpass1 to Vpass4 are also determined taking into consideration the dimensions of the word lines WL. For example, when a typically applied pass voltage is Vpass0, Vpass1 to Vpass4 are set to be lower than Vpass0 in the case where the width dimensions of the word lines WL are larger than the typical value. In contrast, in the case where the width dimensions of the word lines WL are smaller than the typical value, Vpass1 to Vpass4 are set to be higher than Vpass0. However, a voltage that is 1 to 2V higher than the read voltage is generally supplied as the pass voltage. Accordingly, the difference (ΔVpass1) between Vpass1 and Vpass0, the difference (ΔVpass2) between Vpass2 and Vpass0, the difference (ΔVpass3) between Vpass3 and Vpass0, and the difference (ΔVpass4) between Vpass4 and Vpass0 are all about 35 my to 400 mV higher than the differences (ΔVread1 to ΔVread4) of the read voltages. Because Vpass0 is ordinarily around 8 V, ΔVpass1, ΔVpass2, ΔVpass3, and ΔVpass4 are all within 5% of the value of Vpass0.

According to this embodiment, taking into consideration that the dimension variations due to the double spacer process occur every four lines, the respective program voltages Vpgm, verify voltages Vv, read voltages Vread, and pass voltages Vpass are independently applied to the word lines WL in the (4n+1)-th, (4n+2)-th, (4n+3)-th, and (4n+4)-th positions from the given reference position, so as to reduce the inter-cell variation based on the inter-cell interference effect.

### Second Embodiment

### Single Level Cell, Pulse Width Change of Voltage

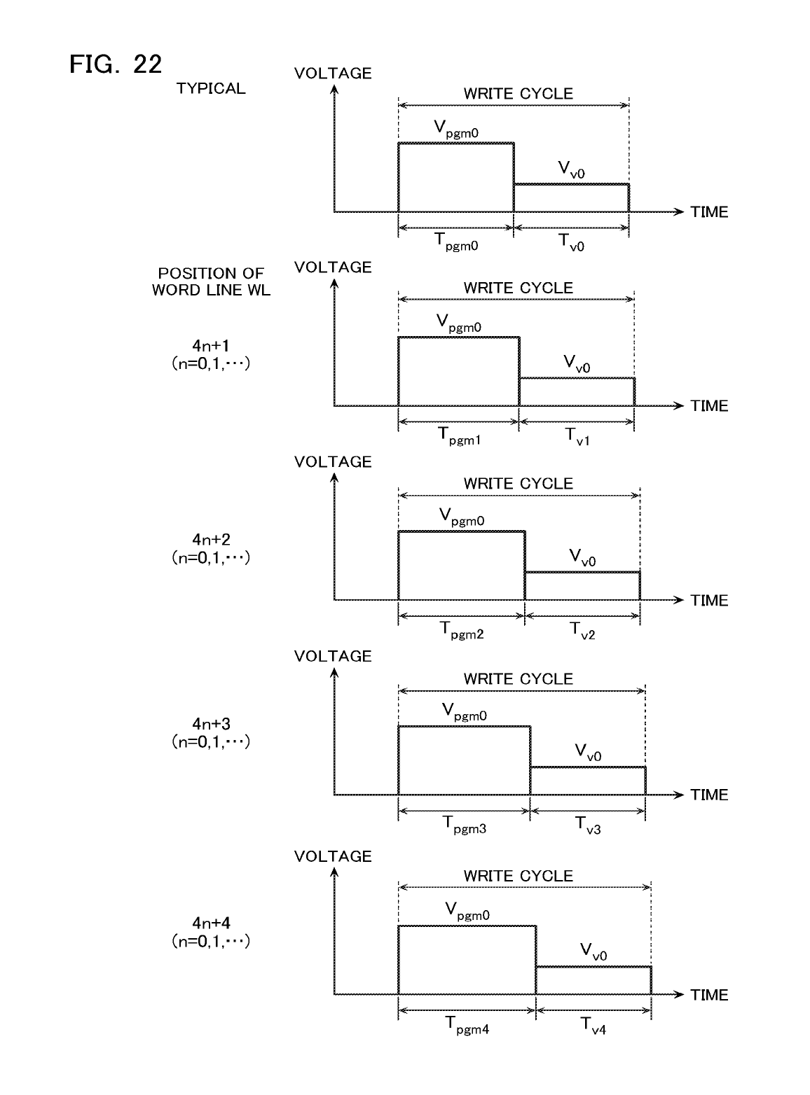

The following describes a second embodiment with reference to FIGS. 22 to 24. In this embodiment, the configuration of the nonvolatile semiconductor memory device including the memory cell array and the operation method using Single Level Cell are similar to those in the first embodiment. Only the voltage application method is different from that of the first embodiment.

Here, in the following description, like reference numerals designate elements corresponding or identical to the elements in the first embodiment, and therefore such elements will not be further elaborated here.

Firstly, as illustrated in FIG. 22, regarding the program voltages, the application times are set as: Tpgm1 for Vpgm0 for the word line WL in the (4n+1)-th (n=0, 1, . . . ) position; Tpgm2 for the word line WL in the (4n+2)-th (n=0, 1, . . . ) position; Tpgm3 for the word line WL in the (4n+3)-th (n=0, 1, . . . ) position; and Tpgm4 for the word line WL in the (4n+4)-th (n=0, 1, . . . ) position, from a given reference position. The values of Tpgm1 to Tpgm4 are determined taking into consideration the dimensions of the word lines WL. For example, when the application time of the typically applied program voltage Vpgm0 is Tpgm0, Tpgm1 to Tpgm4 are set to be smaller than Tpgm0 in the case where the width dimensions of the word lines WL are larger than the typical value. In contrast, in the case where the width dimensions of the word lines WL are smaller than the typical value, Tpgm1 to Tpgm4 are set to be larger than Tpgm0. However, the difference (ΔTpgm1) between Tpgm1 and Tpgm0, the difference (ΔTpgm2) between Tpgm2 and Tpgm0, the difference (ΔTpgm3) between Tpgm3 and Tpgm0, and the difference (ΔTpgm4) between Tpgm4 and Tpgm0 are all within 5% of the value of Tpgm0.

Similarly, as illustrated in FIG. 22, regarding the verify voltages, the application times are set as: Tv1 for Vv0 for the word line WL in the (4n+1)-th (n=0, 1, . . . ) position; Tv2 for the word line WL in the (4n+2)-th (n=0, 1, . . . ) position; Tv3 for the word line WL in the (4n+3)-th (n=0, 1, . . . ) position; and Tv4 for the word line WL in the (4n+4)-th (n=0, 1, . . . ) position, from a given reference position. The values of Tv1 to Tv4 are also determined taking into consideration the dimensions of the word lines WL. For example, when the application time of the typically applied verify voltage Vv0 is Tv0, Tv1 to Tv4 are set to be shorter than Tv0 in the case where the width dimensions of the word lines WL are larger than the typical value. In contrast, in the case where the width dimensions of the word lines WL are smaller than the typical value, Tv1 to Tv4 are set to be longer than Tv0. However, the difference (ΔTv1) between Tv1 and Tv0, the difference (ΔTv2) between Tv2 and Tv0, the difference (ΔTv3) between Tv3 and Tv0, and the difference (ΔTv4) between Tv4 and Tv0 are all within 10% of the value of Tv0.

Here, in this embodiment, the values of the program voltage and the verify voltage are respectively set as Vpgm0 and Vv0 as in a typical manner.

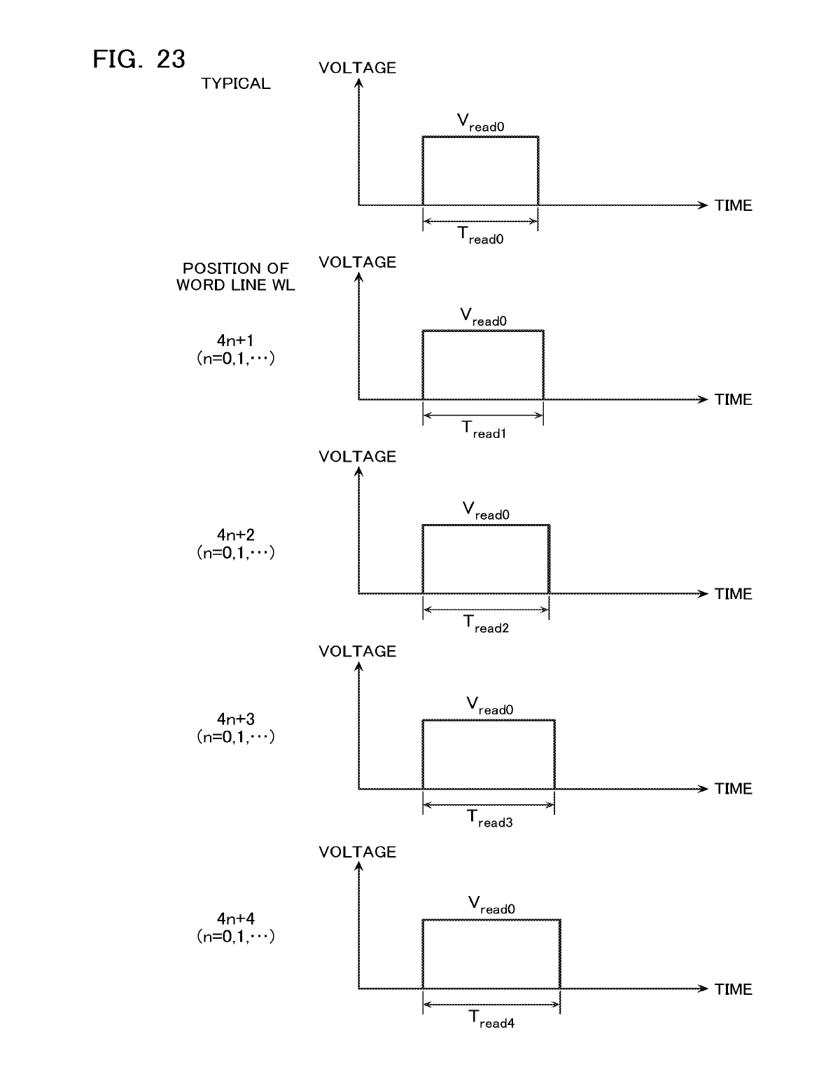

As illustrated in FIG. 23, also regarding the read voltage Vread, the read voltage is applied to the word line WL in the (4n+1)-th (n=0, 1, . . . ) position only for an application time of Tread1, the read voltage is applied to the word line WL in the (4n+2)-th (n=0, 1, . . . ) position only for an application time of Tread2, the read voltage is applied to the word line WL in the (4n+3)-th (n=0, 1, . . . ) position only for Tread3, and the read voltage is applied to the word line WL in the (4n+4)-th (n=0, 1, . . . ) position only for an application time of Tread4, from a given reference position. The values of Tread1 to Tread4 are also determined taking into consideration the dimensions of the word lines WL. For example, when the application time of the typically applied read voltage Vread0 is Tread0, Tread1 to Tread4 are set to be shorter than Tread0 in the case where the width dimensions of the word lines WL are larger than the typical value. In contrast, in the case where the width dimensions of the word lines WL are smaller than the typical value, Tread1 to Tread4 are set to be longer than Tread0. However, the difference (ΔTread1) between Tread1 and Tread0, the difference (ΔTread2) between Tread2 and Tread0, the difference (ΔTread3) between Tread3 and Tread0, and the difference (ΔTread4) between Tread4 and Tread0 are all within 4% of the value of Tread0.

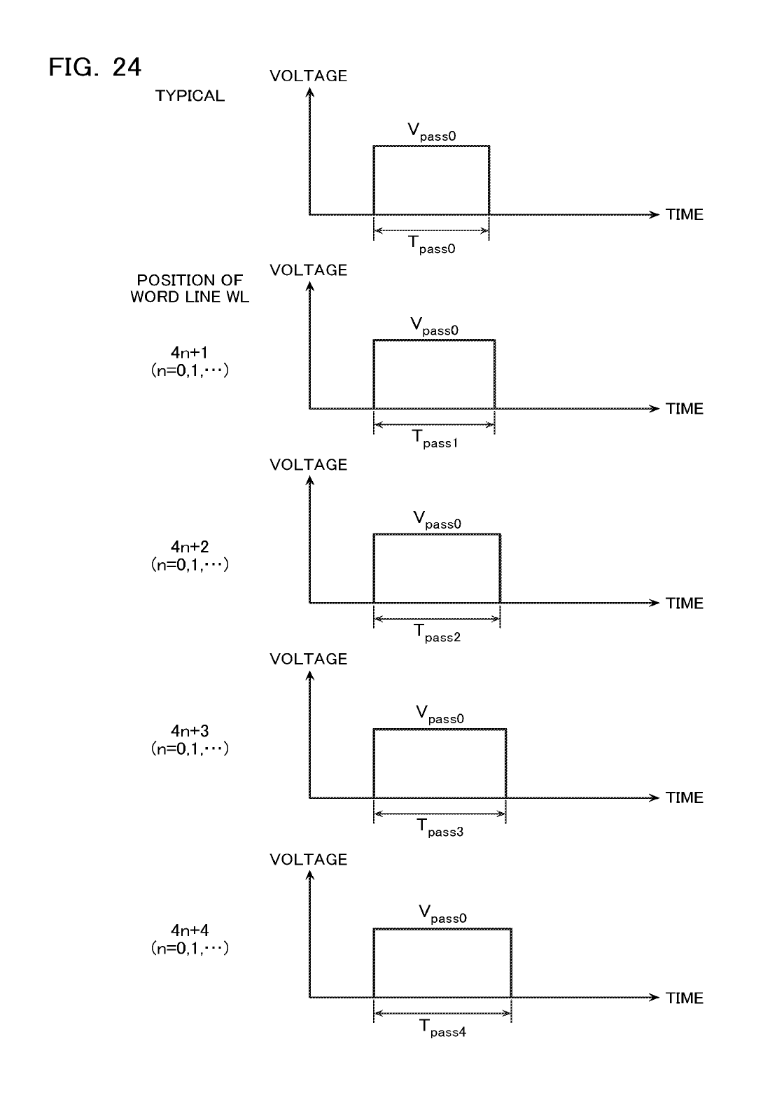

As illustrated in FIG. 24, also regarding the pass voltage Vpass applied to the adjacent word lines WL during a program operation, the pass voltage is applied to the word line WL in the (4n+1)-th (n=0, 1, . . . ) position only for an application time of Tpass1, the pass voltage is applied to the word line WL in the (4n+2)-th (n=0, 1, . . . ) position only for an application time of Tpass2, the pass voltage is applied to the word line WL in the (4n+3)-th (n=0, 1, . . . ) position only for an application time of Tpass3, and the pass voltage is applied to the word line WL in the (4n+4)-th (n=0, 1, . . . ) position only for an application time of Tpass4, from a given reference position. The values of Tpass1 to Tpass4 are also determined taking into consideration the dimensions of the word lines WL. For example, when the application time of the typically applied pass voltage Vpass0 is Tpass0, Tpass1 to Tpass4 are set to be shorter than Tpass0 in the case where the width dimensions of the word lines WL are larger than the typical value. In contrast, in the case where the width dimensions of the word lines WL are smaller than the typical value, Tpass1 to Tpass4 are set to be longer than Tpass0. However, the difference (ΔTpass1) between Tpass1 and Tpass0, the difference (ΔTpass2) between Tpass2 and Tpass0, the difference (ΔTpass3) between Tpass3 and Tpass0, and the difference (ΔTpass4) between Tpass4 and Tpass0 are all within 5% of the value of Tpass0.

According to this embodiment, taking into consideration that the dimension variations due to the double spacer process occur every four lines, the respective times of application, that is, pulse widths of the program voltages Vpgm, the verify voltages Vv, the read voltages Vread, and the pass voltages Vpass to the word lines WL in the (4n+1)-th, (4n+2)-th, (4n+3)-th, and (4n+4)-th positions from the given reference position are independently changed, so as to reduce the inter-cell variation based on the inter-cell interference effect.

### Third Embodiment

### Single Level Cell, Value and Pulse Width Changes of Voltage

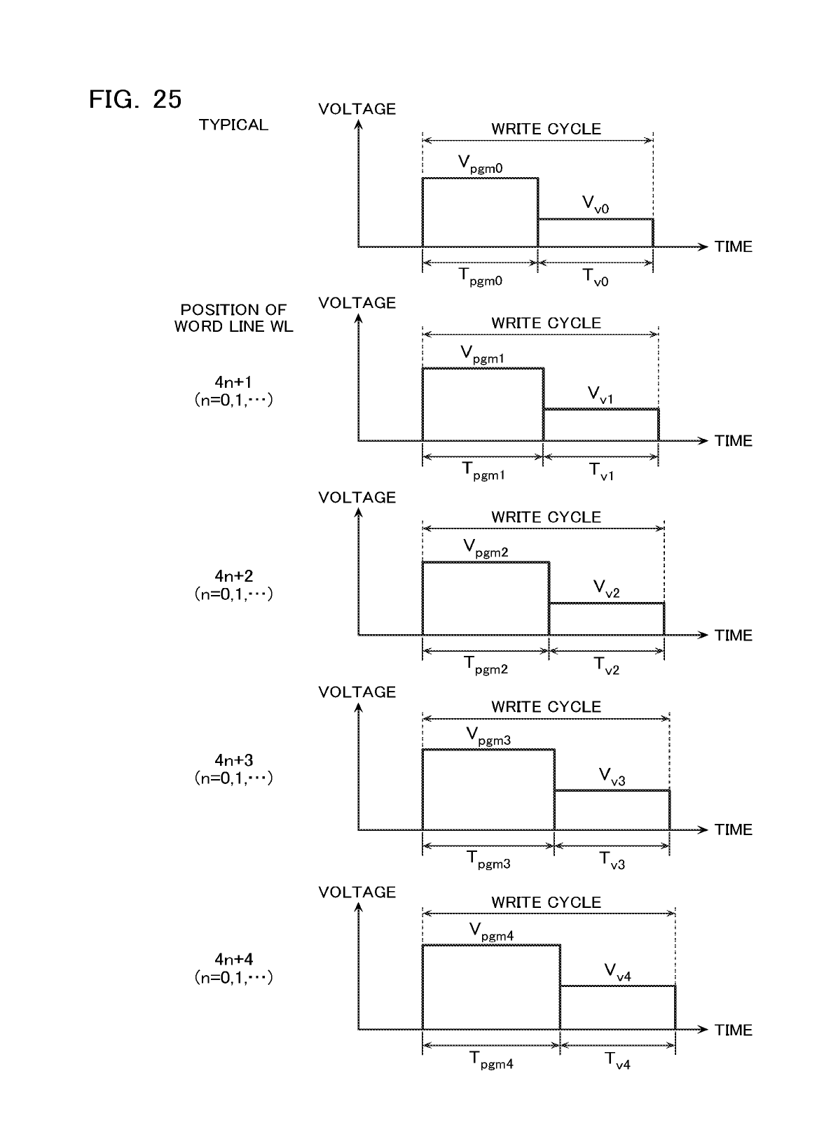

The following describes a third embodiment with reference to FIGS. 25 to 27. In this embodiment, the configuration of the nonvolatile semiconductor memory device including the memory cell array and the operation method using Single Level Cell are similar to those in the first embodiment. Only the voltage application method is different from that of the first embodiment.

Here, in the following description, like reference numerals designate elements corresponding or identical to the elements in the first embodiment, and therefore such elements will not be further elaborated here.

Firstly, as illustrated in FIG. 25, regarding the program voltages, the program voltage is set to Vpgm1 and the application time is set to Tpgm1 for the word line WL in the (4n+1)-th (n=0, 1, . . . ) position, the program voltage is set to Vpgm2 and the application time is set to Tpgm2 for the word line WL in the (4n+2)-th (n=0, 1, . . . ) position, the program voltage is set to Vpgm3 and the application time is set to Tpgm3 for the word line WL in the (4n+3)-th (n=0, 1, . . . ) position, and the program voltage is set to Vpgm4 and the application time is set to Tpgm4 for the word line WL in the (4n+4)-th (n=0, 1, . . . ) position, from a given reference position. The values of Vpgm1 to Vpgm4 and the values of Tpgm1 to Tpgm4 are determined taking into consideration the dimensions of the word lines WL as described in the first and second embodiments. That is, when a typically applied program voltage is Vpgm0 and the application time is Tpgm0, Vpgm1 to Vpgm4 are set to be lower than Vpgm0 and Tpgm1 to Tpgm4 are set to be smaller than Tpgm0 in the case where the width dimensions of the word lines WL are larger than the typical value. In contrast, in the case where the width dimensions of the word lines WL are smaller than the typical value, Vpgm1 to Vpgm4 are set to be higher than Vpgm0 and Tpgm1 to Tpgm4 are set to be larger than Tpgm0. However, ΔVpgm1, ΔVpgm2, ΔVpgm3, and ΔVpgm4 are all within 5% of the value of Vpgm0 as described in the first embodiment, and ΔTpgm1, ΔTpgm2, ΔTpgm3, and ΔTpgm4 are all within 5% of the value of Tpgm0 as described in the second embodiment.

Similarly, as illustrated in FIG. 25, regarding the verify voltages, the verify voltage is set to Vv1 and the application time is set to Tv1 for the word line WL in the (4n+1)-th (n=0, 1, . . . ) position, the verify voltage is set to Vv2 and the application time is set to Tv2 for the word line WL in the (4n+2)-th (n=0, 1, . . . ) position, the verify voltage is set to Vv3 and the application time is set to Tv3 for the word line WL in the (4n+3)-th (n=0, 1, . . . ) position, and the verify voltage is set to Vv4 and the application time is set to Tv4 for the word line WL in the (4n+4)-th (n=0, 1, . . . ) position, from a given reference position. The values of Vv1 to Vv4 and the values of Tv1 to Tv4 are also determined taking into consideration the dimensions of the word lines WL as described in the first and second embodiments. That is, when a typically applied verify voltage is Vv0 and the application time is Tv0, Vv1 to Vv4 are set to be lower than Vv0 and Tv1 to Tv4 are set to be smaller than Tv0 in the case where the width dimensions of the word lines WL are larger than the typical value. In contrast, in the case where the width dimensions of the word lines WL are smaller than the typical value, Vv1 to Vv4 are set to be higher than Vv0 and Tv1 to Tv4 are set to be larger than Tv0. However, ΔVv1, ΔVv2, ΔVv3, and ΔVv4 are all within 10% of the value of Vv0 as described in the first embodiment, and ΔTv1, ΔTv2, ΔTv3, and ΔTv4 are all within 10% of the value of Tv0 as described in the second embodiment.

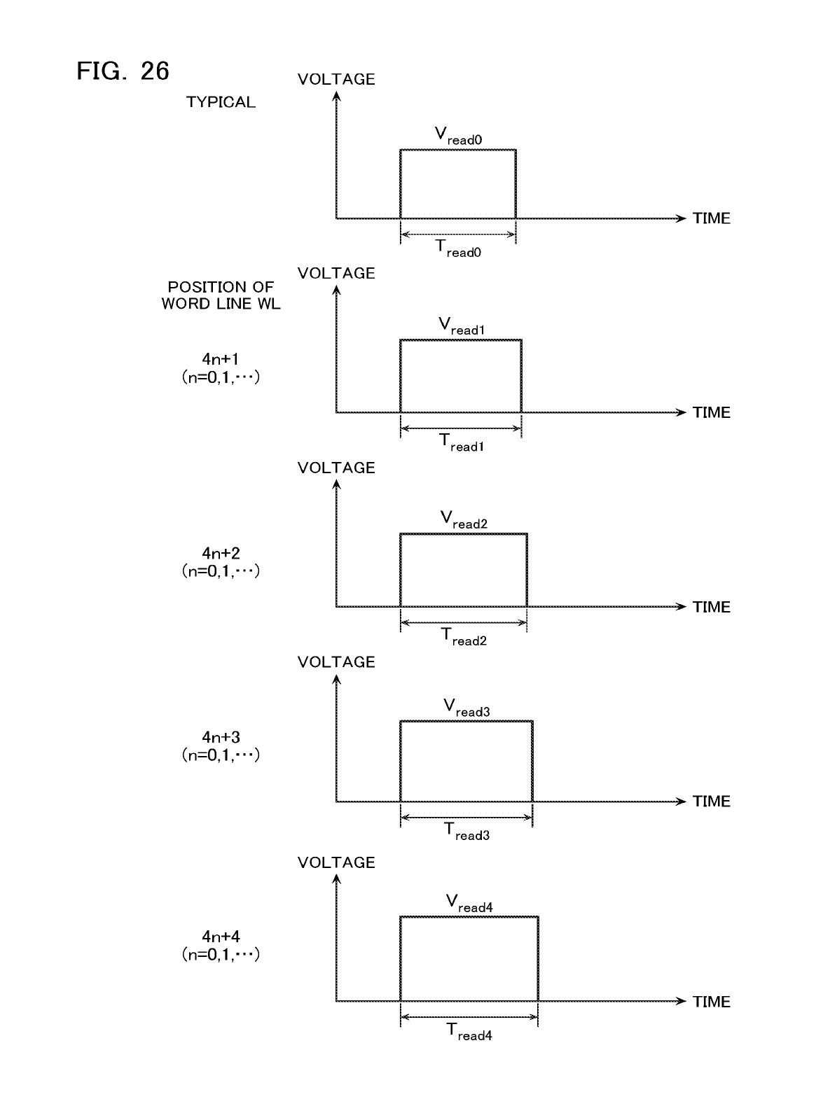

As illustrated in FIG. 26, also regarding the read voltage Vread, the read voltage is set to Vread1 and the application time is set to Tread1 for word line WL in the (4n+1)-th (n=0, 1, . . . ) position, the read voltage is set to Vread2 and the application time is set to Tread2 for the word line WL in the (4n+2)-th (n=0, 1, . . . ) position, the read voltage is set to Vread3 and the application time is set to Tread3 for the word line WL in the (4n+3)-th (n=0, 1, . . . ) position, and the read voltage is set to Vread4 and the application time is set to Tread4 for the word line WL in the (4n+4)-th (n=0, 1, . . . ) position, from a given reference position. The values of Vread1 to Vread4 and the values of Tread1 to Tread4 are also determined taking into consideration the dimensions of the word lines WL as described in the first and second embodiments. That is, when a typically applied read voltage is Vread0 and the application time is Tread0, Vread1 to Vread4 are set to be lower than Vread0 and Tread1 to Tread4 are set to be smaller than Tread0 in the case where the width dimensions of the word lines WL are larger than the typical value. In contrast, in the case where the width dimensions of the word lines WL are smaller than the typical value, Vpgm1 to Vread4 are set to be higher than Vread0 and Tread1 to Tread4 are set to be larger than Tread0. However, ΔVread1, ΔVread2, ΔVread3, and ΔVread4 are all within 4% of the value of Vread0 as described in the first embodiment, and ΔTread1, ΔTread2, ΔTread3, and ΔTread4 are all within 4% of the value of Tread0 as described in the second embodiment.

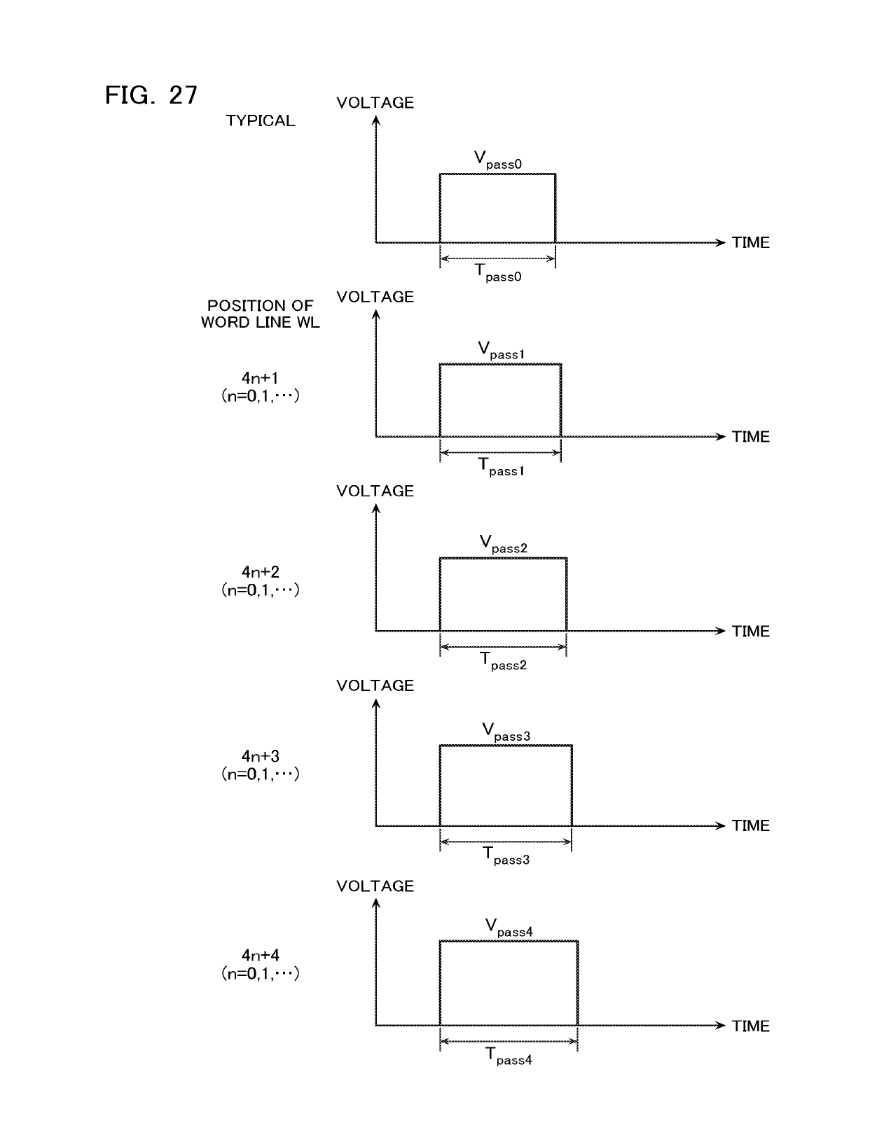

As illustrated in FIG. 27, also regarding the pass voltage Vpass applied to the adjacent word lines WL during a program operation, the pass voltage is set to Vpass1 and the application time is set to Tpass1 for word line WL in the (4n+1)-th (n=0, 1, . . . ) position, the pass voltage is set to Vpass2 and the application time is set to Tpass2 for the word line WL in the (4n+2)-th (n=0, 1, . . . ) position, the pass voltage is set to Vpass3 and the application time is set to Tpass3 for the word line WL in the (4n+3)-th (n=0, 1, . . . ) position, and the pass voltage is set to Vpass4 and the application time is set to Tpass4 for the word line WL in the (4n+4)-th (n=0, 1, . . . ) position, from a given reference position. The values of Vpass1 to Vpass4 and the values of Tpass1 to Tpass4 are also determined taking into consideration the dimensions of the word lines WL as described in the first and second embodiments. That is, when a typically applied pass voltage is Vpass0 and the application time is Tpass0, Vpass1 to Vpass4 are set to be lower than Vpass0 and Tpass1 to Tpass4 are set to be smaller than Tpass0 in the case where the width dimensions of the word lines WL are larger than the typical value. In contrast, in the case where the width dimensions of the word lines WL are smaller than the typical value, Vpass1 to Vpass4 are set to be higher than Vpass0 and Tpass1 to Tpass4 are set to be larger than Tpass0. However, ΔVpass1, ΔVpass2, ΔVpass3, and ΔVpass4 are all within 5% of the value of Vpass0 as described in the first embodiment, and ΔTpass1, ΔTpass2, ΔTpass3, and ΔTpass4 are all within 5% of the value of Tpass0 as described in the second embodiment.

According to this embodiment, taking into consideration that the dimension variations due to the double spacer process occur every four lines, the respective program voltages Vpgm, verify voltages Vv, read voltages Vread, and pass voltages Vpass to the word lines WL in the (4n+1)-th, (4n+2)-th, (4n+3)-th, and (4n+4)-th positions from the given reference position and the respective times of application, that is, pulse widths of these voltages are independently changed, so as to reduce the inter-cell variation based on the inter-cell interference effect.

### Fourth Embodiment

### Multi Level Cell, Value Change of Voltage

The following describes a fourth embodiment. This embodiment is similar to the first to third embodiments in the configuration of the nonvolatile semiconductor memory device including the memory cell array, but is different from the first to third embodiments in use of an operation method using Multi Level Cell.

Here, in the following description, like reference numerals designate elements corresponding or identical to the elements in the first embodiment, and therefore such elements will not be further elaborated here.

### [Operation Method Using Multi Level Cell]

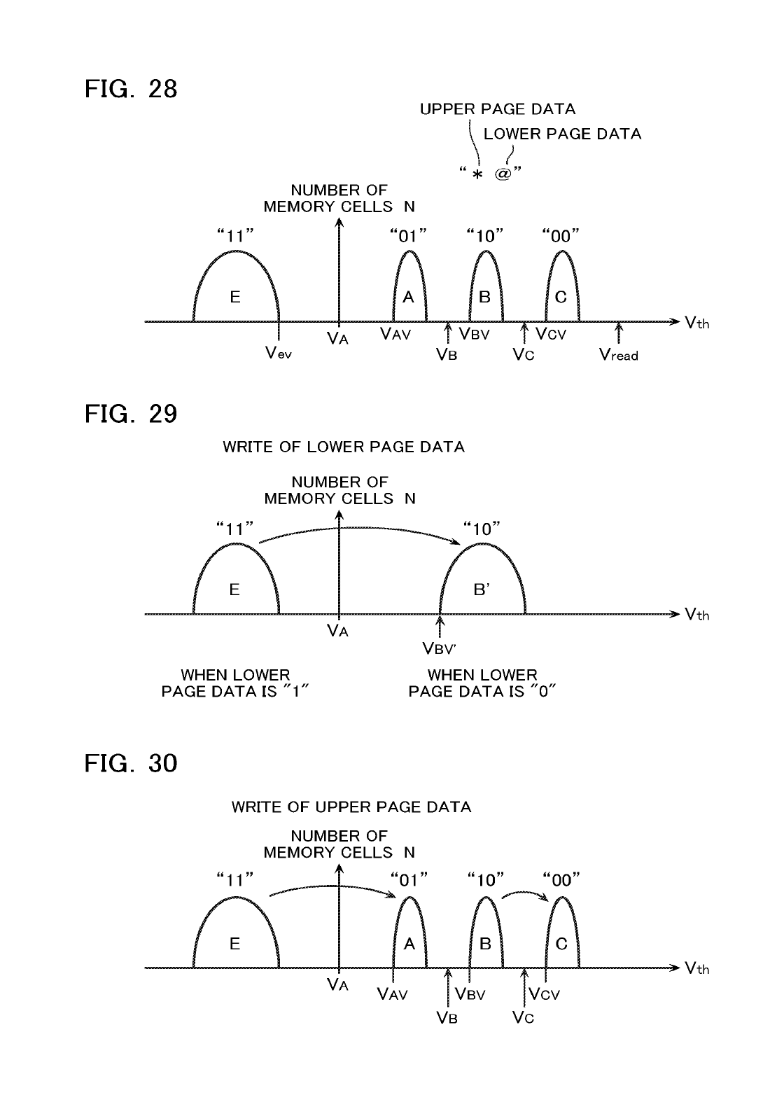

A description will be given of Multi Level Cell using a NAND-type flash memory having the configuration described in the first embodiment with reference to FIG. 28 to FIG. 30. According to the NAND-type flash memory, as illustrated in FIG. 28, the value of the threshold voltage in one memory cell can be controlled, for example, by four values so as to store 2-bit data in one memory cell MC. A description will be given of a four-value-data storage method as an example below. Also in the case where a multi-valued-data storage method using eight-valued data (of 3 bit) or data with having more values is used other than the above, only the number of threshold voltage distributions is different and the basic principle is similar.

To store 2-bit information, four types of threshold voltage distributions (E and A to C) are disposed corresponding to four pieces of data of “11,” “01,” “10,” and “00” to write and read information. That is, any of four pieces of bit information (11, 01, 10, and 00) is assigned to each of the four threshold voltage distributions (E and A to C). Corresponding to this 2-bit data, two sub-pages are formed. That is, the two sub-pages are an upper page UPPER and a lower page LOWER.

At the time of the read operation of these four pieces of data, a read voltage is applied to the selected word line WL coupled to the memory cell MC so as to detect conduction or non-conduction of the memory cell MC before the read operation. The voltage value of the read voltage applied to the selected word line WL can be set to the voltages VA, VB, and VC (three values) between the upper limits and the lower limits of the respective threshold voltage distributions as illustrated in FIG. 28 corresponding to the four threshold voltage distributions of the memory cell (see FIG. 28). The read voltage VA is the lowest voltage, and the voltage value increases in the order corresponding to VB and VC. Here, the voltage Vread applied to the non-selection memory cell MC at the time of the read operation is set to a voltage larger than the upper limit value of the threshold voltage distribution C to which data “00” is assigned. That is, the voltage Vread is a voltage applied to the non-selection memory cell within the NAND cell in the case where data is read, and causes conduction of the non-selection memory cell irrespective of the holding data.

In FIG. 28, the voltages VAV, VBV, and VCV denote verify voltages applied to confirm whether the write has been completed in the case where the write to the respective threshold voltage distributions is performed.

Furthermore, Vev is an erase verify voltage applied to the memory cell to confirm whether the erase has been completed in the case where the data of the memory cell is erased, and has a negative value. The magnitude of Vev is determined taking into consideration the influence of interference of the adjacent memory cell. The magnitude relationship between the respective voltages described above is Vev <VA<VAV<VB<VBV<VC<VCV<Vread.

Here, the erase verify voltage Vev has a negative value as described above. However, the voltage applied to the control gate of the memory cell MC in an actual erase verify operation does not have a negative value, but has a zero or positive value. That is, in the actual erase verify operation, a positive voltage is supplied to the back gate of the memory cell MC and a voltage having a zero or positive value smaller than the back gate voltage is applied to the control gate of the memory cell MC.

The threshold voltage distribution E of the memory cell after block erasure has a negative value as the upper limit value, and data “11” is assigned to the threshold voltage distribution E. The memory cells having data “01,” “10,” and “00” in write states have the respective positive threshold voltage distributions A, B, and C (the lower limit values of A, B, and C also have positive values). The threshold voltage distribution A of data “01” has the lowest voltage value, the threshold voltage distribution C of data “00” has the highest voltage value, and the threshold voltage distribution B of data “10” has the intermediate voltage value between data “01” and data “00.” Here, the threshold voltage distributions illustrated in FIG. 28 are only examples. For example, while in FIG. 28 the threshold voltage distributions A, B, and C are all described as the positive threshold voltage distributions, the threshold voltage distribution A may be a distribution of negative voltages and the threshold voltage distributions B and C may be distributions of positive voltages. The threshold voltage distribution E may be a distribution of positive voltages.

The 2-bit data of one memory cell includes lower page data and upper page data. The lower page data and the upper page data are written to the memory cell by different write operations, that is, two write operations. When data “*@” is noted, * denotes the upper page data and @ denotes the lower page data.

Firstly, a description will be given of a write of the lower page data with reference to FIG. 29. Assume that all the memory cells have the threshold voltage distribution E in the erased states, and store data “11.” As illustrated in FIG. 29, when the lower page data is written, the threshold voltage distribution E of the memory cell is divided into two threshold voltage distributions (E and B′) corresponding to the value (“1” or “0”) of the lower page data. That is, in the case where the value of the lower page data is “1,” the threshold voltage distribution E in the erased state is maintained.

On the other hand, in the case where the value of the lower page data is “0,” a high electric field is applied to the tunnel oxide film of the memory cell to inject electrons into the floating gate electrode so as to increase the threshold voltage Vth of the memory cell by a predetermined amount. Specifically, a verify potential VBV′ is set, and the write operation is repeated until the voltage becomes a threshold voltage equal to or more than this verify voltage VBV′. As a result, the memory cell changes to a write state (data “10”).

The following describes a write of the upper page data with reference to FIG. 30. The upper page data is written based on write data (the upper page data), which is input from outside of the chip, and the lower page data, which has already been written to the memory cell.

That is, as illustrated in, FIG. 30, in the case where the value of the upper page data is “1,” a high electric field is not applied to the tunnel oxide film of the memory cell so as to prevent the threshold voltage Vth of the memory cell being increased. As a result, the memory cell of data “11” (the threshold voltage distribution E in the erased state) still maintains data “11” and the memory cell of data “10” (the threshold voltage distribution B′) still maintains data “10.” However, a normal verify voltage VBV larger than the above-described verify voltage VBV′ is used to adjust the lower limit value of the threshold voltage distribution so as to form the threshold voltage distribution B having a narrowed width of the threshold voltage distribution.

On the other hand, in the case where the value of the upper page data is “0,” a high electric field is applied to the tunnel oxide film of the memory cell to inject electrons into the floating gate electrode so as to increase the threshold voltage Vth of the memory cell by a predetermined amount. As a result, the memory cell of data “11” (the threshold voltage distribution E in the erased state) changes to have data “01” of the threshold voltage distribution A, and the memory cell of data “10” changes to have data “00” of the threshold voltage distribution C. At this time, the verify voltages VAV and VCV are used to adjust the lower limit values of the threshold voltage distributions A and C.

This is one example of the data write method in a general four-value-data storage method. This is only one example, and various methods of the assignment of data to the threshold voltage distribution, the procedure of the write operation, and similar process can be employed other than these methods. Also in a multibit storage method having three or more bits, only an operation for dividing the threshold voltage distribution into eight distributions corresponding to the upper page data is added to the above-described operation. Accordingly, the basic operation is similar.

### Operation According to this Embodiment

In this embodiment, similarly to the first embodiment, different program voltages, verify voltages, read voltages, and pass voltages are changed for different groups of the four word lines WL.

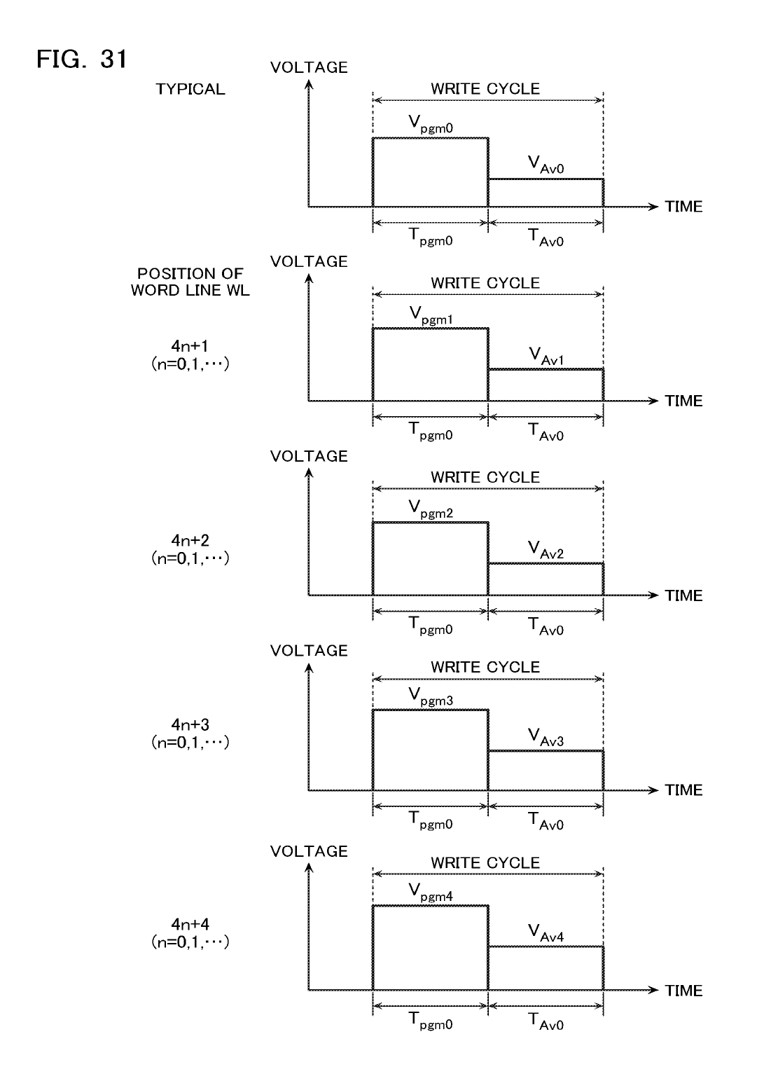

That is, as illustrated in FIG. 31, the program voltages are set as: Vpgm1 for the word line WL in the (4n+1)-th (n=0, 1, . . . ) position; Vpgm2 for the word line WL in the (4n+2)-th (n=0, 1, . . . ) position; Vpgm3 for the word line WL in the (4n+3)-th (n=0, 1, . . . ) position; and Vpgm4 for the word line WL in the (4n+4)-th (n=0, 1, . . . ) position, from a given reference position. Similarly to the first embodiment, the values of Vpgm1 to Vpgm4 are determined taking into consideration the dimensions of the word lines WL. When a typically applied program voltage is Vpgm0, Vpgm1 to Vpgm4 are set to be lower than Vpgm0 in the case where the width dimensions of the word lines WL are larger than the typical value. In contrast, in the case where the width dimensions of the word lines WL are smaller than the typical value, Vpgm1 to Vpgm4 are set to be higher than Vpgm0. However, ΔVpgm1, ΔVpgm2, ΔVpgm3, and ΔVpgm4 are all within 5% of the value of Vpgm0.

Similarly, as illustrated in FIG. 31, the verify voltages VAV are set as: VAV1 for the word line WL in the (4n+1)-th (n=0, 1, . . . ) position; VAV2 for the word line WL in the (4n+2)-th (n=0, 1, . . . ) position; VAV3 for the word line WL in the (4n+3)-th (n=0, 1, . . . ) position; and VAV4 for the word line WL in the (4n+4)-th (n=0, 1, . . . ) position, from a given reference position. The values of VAV1 to VAV4 are also determined taking into consideration the dimensions of the word lines WL, similarly to the first embodiment. When a typically applied verify voltage is VAV0, VAV1 to VAV4 are set to be lower than VAV0 in the case where the width dimensions of the word lines WL are larger than the typical value. In contrast, in the case where the width dimensions of the word lines WL are smaller than the typical value, VAV1 to VAV4 are set to be higher than VAV0. However, the difference (ΔVAV1) between VAV1 and VAV0, the difference (ΔVAV2) between VAV2 and VAV0, the difference (ΔVAV3) between VAV3 and VAV0, and the difference (ΔVAV4) between VAV4 and VAV0 are all within 10% of the value of VAV0.

In this embodiment, the application times (pulse widths) of the program voltages Vpgm1 to Vpgm4 and the application times (pulse widths) of the verify voltages VAV1 to VAV4 are respectively set as Tpgm0 and TAV0 as in a typical manner.

In the above description, for the verify voltages, the example of VAV is described. The same applies to VBV and VCV.

As described in FIG. 20, also regarding the read voltage Vread, Vread1 is applied to the word line WL in the (4n+1)-th (n=0, 1, . . . ) position, Vread2 is applied to the word line WL in the (4n+2)-th (n=0, 1, . . . ) position, Vread3 is applied to the word line WL in the (4n+3)-th (n=0, 1, . . . ) position, and Vread4 is applied to the word line WL in the (4n+4)-th (n=0, 1, . . . ) position, from a given reference position. The values of Vread1 to Vread4 are also determined taking into consideration the dimensions of the word lines WL, similarly to the first embodiment. When a typically applied read voltage is Vread0, Vread1 to Vread4 are set to be lower than Vread0 in the case where the width dimensions of the word lines WL are larger than the typical value. In contrast, in the case where the width dimensions of the word lines WL are smaller than the typical value, Vread1 to Vread4 are set to be higher than Vread0. However, the read voltage Vread is considerably affected by the adjacent read voltage during the read. Accordingly, in the case where the width dimensions of the word lines WL are changed by several nm and thus the distances to the adjacent word lines WL are changed by several nm, ΔVread1, ΔVread2, ΔVread3, and ΔVread4 are all about 20 mV to 300 mV. Because Vread0 is ordinarily around 7 V, ΔVread1, ΔVread2, ΔVread3, and ΔVread4 are all within 4% of the value of Vread0.

As described in FIG. 21, also regarding the pass voltage Vpass applied to the adjacent word lines WL during a program operation, Vpass1 is applied to the word line WL in the (4n+1)-th (n=0, 1, . . . ) position, Vpass2 is applied to the word line WL in the (4n+2)-th (n=0, 1, . . . ) position, Vpass3 is applied to the word line WL in the (4n+3)-th (n=0, 1, . . . ) position, and Vpass4 is applied to the word line WL in the (4n+4)-th (n=0, 1, . . . ) position, from a given reference position. The values of Vpass1 to Vpass4 are also determined taking into consideration the dimensions of the word lines WL, similarly to the first embodiment. When a typically applied pass voltage is Vpass0, Vpass1 to Vpass4 are set to be lower than Vpass0 in the case where the width dimensions of the word lines WL are larger than the typical value. In contrast, in the case where the width dimensions of the word lines WL are smaller than the typical value, Vpass1 to Vpass4 are set to be higher than Vpass0. However, a voltage that is 1 to 2V higher than the read voltage is generally supplied as the pass voltage. ΔVpass1, ΔVpass2, ΔVpass3, and ΔVpass4 are all about 35 mV to 400 mV higher than the differences (ΔVread1 to ΔVread4) of the read voltages. Because Vpass0 is ordinarily around 8 V, ΔVpass1, ΔVpass2, ΔVpass3, and ΔVpass4 are all within 5% of the value of Vpass0.

According to this embodiment, taking into consideration that the dimension variations due to the double spacer process occur every four lines, the respective program voltages Vpgm, verify voltages VAV, VBV, and VCV, read voltages Vread, and pass voltages Vpass are independently changed for the word lines WL in the (4n+1)-th, (4n+2)-th, (4n+3)-th, and (4n+4)-th positions from the given reference position, so as to reduce the inter-cell variation based on the inter-cell interference effect.

### Fifth Embodiment

### Multi Level Cell, Pulse Width Change of Voltage

The following describes a fifth embodiment. In this embodiment, the configuration of the nonvolatile semiconductor memory device including the memory cell array and the operation method using Multi Level Cell are similar to those in the fourth embodiment. Only the voltage application method is different from that of the fourth embodiment.

Here, in the following description, like reference numerals designate elements corresponding or identical to the elements in the fourth embodiment, and therefore such elements will not be further elaborated here.

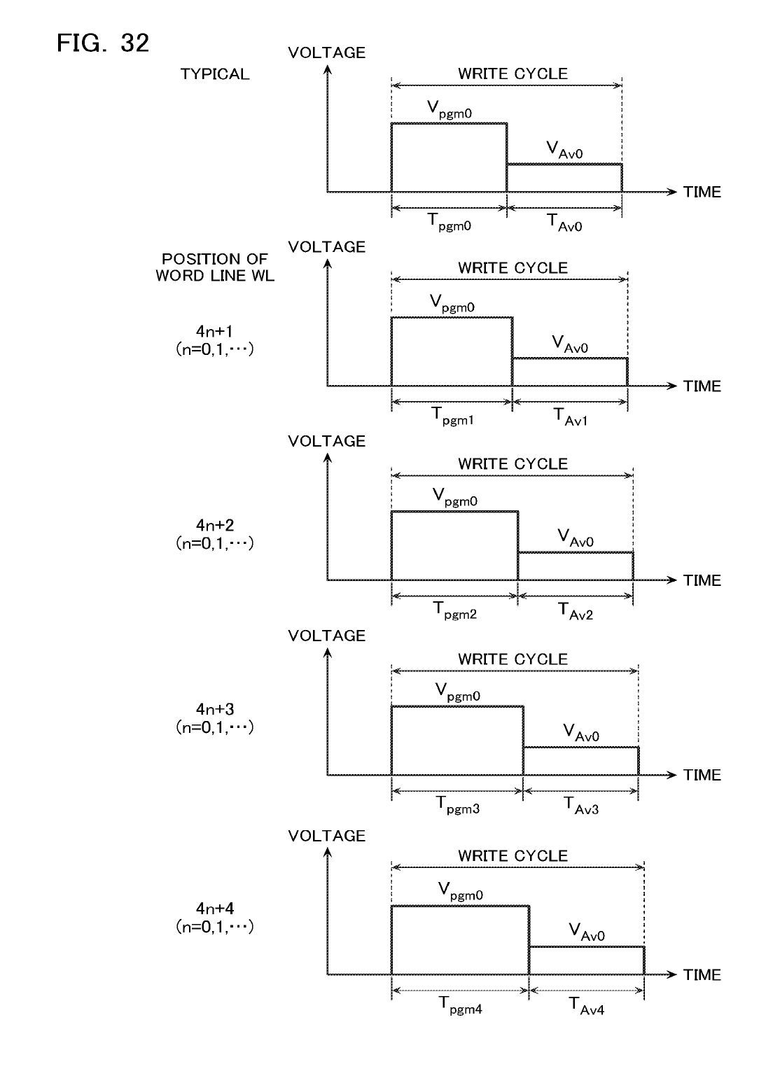

Firstly, as illustrated in FIG. 32, regarding the program voltages, the application times are set as: Tpgm1 for Vpgm0 for the word line WL in the (4n+1)-th (n=0, 1, . . . ) position; Tpgm2 for the word line WL in the (4n+2)-th (n=0, 1, . . . ) position; Tpgm3 for the word line WL in the (4n+3)-th (n=0, 1, . . . ) position; and Tpgm4 for the word line WL in the (4n+4)-th (n=0, 1, . . . ) position, from a given reference position. Similarly to the second embodiment, the values of Tpgm1 to Tpgm4 are determined taking into consideration the dimensions of the word lines WL. When the application time of the typically applied program voltage Vpgm0 is Tpgm0, Tpgm1 to Tpgm4 are set to be smaller than Tpgm0 in the case where the width dimensions of the word lines WL are larger than the typical value. In contrast, in the case where the width dimensions of the word lines WL are smaller than the typical value, Tpgm1 to Tpgm4 are set to be larger than Tpgm0. However, ΔTpgm1, ΔTpgm2, ΔTpgm3, and ΔTpgm4 are all within 5% of the value of Tpgm0.

Similarly, as illustrated in FIG. 32, regarding the verify voltages VAV, the application times are set as: TAV1 for VAV0 for the word line WL in the (4n+1)-th (n=0, 1, . . . ) position; TAV2 for the word line WL in the (4n+2)-th (n=0, 1, . . . ) position; TAV3 for the word line WL in the (4n+3)-th (n=0, 1, . . . ) position; and TAV4 for the word line WL in the (4n+4)-th (n=0, 1, . . . ) position, from a given reference position. The values of TAV1 to TAV4 are also determined taking into consideration the dimensions of the word lines WL, similarly to the second embodiment. When the application time of the typically applied verify voltage VAV0 is TAV0, TAV1 to TAV4 are set to be shorter than TAV0 in the case where the width dimensions of the word lines WL are larger than the typical value. In contrast, in the case where the width dimensions of the word lines WL are smaller than the typical value, TAV1 to TAV4 are set to be longer than TAV0. However, the difference (ΔTAV1) between TAV1 and TAV0, the difference (ΔTAV2) between TAV2 and TAV0, the difference (ΔTAV3) between TAV3 and TAV0, and the difference (ΔTAV4) between TAV4 and TAV0 are all within 10% of the value of TAV0.

Here, in this embodiment, the values of the program voltage and the verify voltage are respectively set as Vpgm0 and VAV0 as in a typical manner.

In the above description, for the verify voltages, the example of VAV is described. The same applies to VBV and VCV.

As described in FIG. 23, also regarding the read voltage Vread, the read voltage is applied to the word line WL in the (4n+1)-th (n=0, 1, . . . ) position only for an application time of Tread1, the read voltage is applied to the word line WL in the (4n+2)-th (n=0, 1, . . . ) position only for an application time of Tread2, the read voltage is applied to the word line WL in the (4n+3)-th (n=0, 1, . . . ) position only for an application time of Tread3, and the read voltage is applied to the word line WL in the (4n+4)-th (n=0, 1, . . . ) position only for an application time of Tread4, from a given reference position. Similarly to the second embodiment, the values of Tread1 to Tread4 are also determined taking into consideration the dimensions of the word lines WL. When the application time of the typically applied read voltage Vread0 is Tread0, Tread0 to Tread4 are set to be shorter than Tread0 in the case where the width dimensions of the word lines WL are larger than the typical value. In contrast, in the case where the width dimensions of the word lines WL are smaller than the typical value, Tread1 to Tread4 are set to be longer than Tread0. However, ΔTread1, ΔTread2, ΔTread3, and ΔTread4 are all within 4% of the value of Tread0.

As described in FIG. 24, also regarding the pass voltage Vpass applied to the adjacent word lines WL during a program operation, the pass voltage is applied to the word line WL in the (4n+1)-th (n=0, 1, . . . ) position only for an application time of Tpass1, the pass voltage is applied to the word line WL in the (4n+2)-th (n=0, 1, . . . . ) position only for an application time of Tpass2, the pass voltage is applied to the word line WL in the (4n+3)-th (n=0, 1, . . . ) position only for an application time of Tpass3, and the pass voltage is applied to the word line WL in the (4n+4)-th (n=0, 1, . . . ) position only for an application time of Tpass4, from a given reference position. Similarly to the second embodiment, the values of Tpass1 to Tpass4 are also determined taking into consideration the dimensions of the word lines WL. When the application time of the typically applied pass voltage Vpass0 is Tpass0, Tpass1 to Tpass4 are set to be shorter than Tpass0 in the case where the width dimensions of the word lines WL are larger than the typical value. In contrast, in the case where the width dimensions of the word lines WL are smaller than the typical value, Tpass1 to Tpass4 are set to be longer than Tpass0. However, ΔTpass1, ΔTpass2, ΔTpass3, and ΔTpass4 are all within 5% of the value of Tpass0.

According to this embodiment, taking into consideration that the dimension variations due to the double spacer process occur every four lines, the respective times of application, that is, pulse widths of the program voltages Vpgm, the verify voltages VAV, VBV, and VCV, the read voltages Vread, and the pass voltages Vpass to the word lines WL in the (4n+1)-th, (4n+2)-th, (4n+3)-th, and (4n+4)-th positions from the given reference position are independently changed, so as to reduce the inter-cell variation based on the inter-cell interference effect.

### Sixth Embodiment

### Multi Level Cell, Value and Pulse Width Changes of Voltage

The following describes a sixth embodiment. In this embodiment, the configuration of the nonvolatile semiconductor memory device including the memory cell array and the operation method using Multi Level Cell are similar to those in the fourth embodiment. Only the voltage application method is different from that of the fourth embodiment.

Here, in the following description, like reference numerals designate elements corresponding or identical to the elements in the fourth embodiment, and therefore such elements will not be further elaborated here.

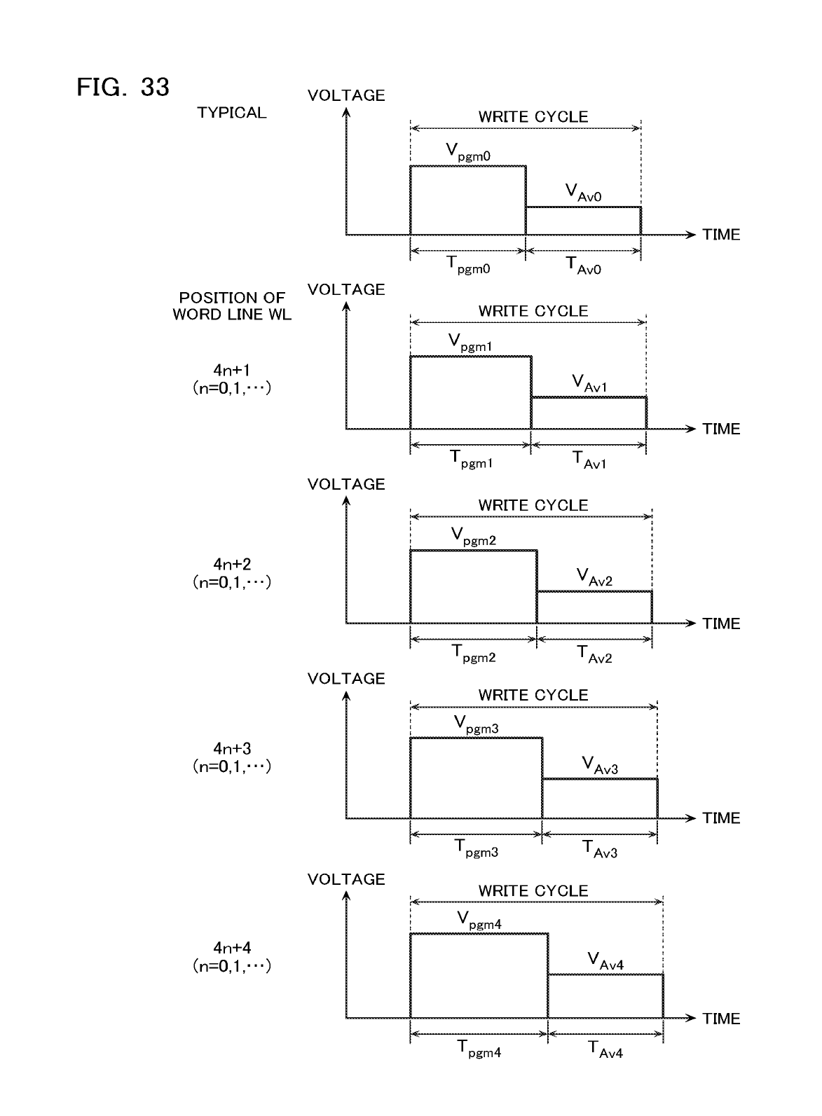

Firstly, as illustrated in FIG. 33, regarding the program voltages, the program voltage is set to Vpgm1 and the application time is set to Tpgm1 for the word line WL in the (4n+1)-th (n=0, 1, . . . ) position, the program voltage is set to Vpgm2 and the application time is set to Tpgm2 for the word line WL in the (4n+2)-th (n=0, 1, . . . ) position, the program voltage is set to Vpgm3 and the application time is set to Tpgm3 for the word line WL in the (4n+3)-th (n=0, 1, . . . ) position, and the program voltage is set to Vpgm4 and the application time is set to Tpgm4 for the word line WL in the (4n+4)-th (n=0, 1, . . . ) position, from a given reference position. The values of Vpgm1 to Vpgm4 and the values of Tpgm1 to Tpgm4 are determined taking into consideration the dimensions of the word lines WL as described in the fourth and fifth embodiments. That is, when a typically applied program voltage is Vpgm0 and the application time is Tpgm0, Vpgm1 to Vpgm4 are set to be lower than Vpgm0 and Tpgm1 to Tpgm4 are set to be smaller than Tpgm0 in the case where the width dimensions of the word lines WL are larger than the typical value. In contrast, in the case where the width dimensions of the word lines WL are smaller than the typical value, Vpgm1 to Vpgm4 are set to be higher than Vpgm0 and Tpgm1 to Tpgm4 are set to be larger than Tpgm0. However, ΔVpgm1, ΔVpgm2, ΔVpgm3, and ΔVpgm4 are all within 5% of the value of Vpgm0 as described in the fourth embodiment, and ΔTpgm1, ΔTpgm2, ΔTpgm3, and ΔTpgm4 are all within 5% of the value of Tpgm0 as described in the fifth embodiment.

Similarly, as illustrated in FIG. 33, regarding the verify voltages VAV, the verify voltage is set to VAV1 and the application time is set to TAV1 for the word line WL in the (4n+1)-th (n=0, 1, . . . ) position, the verify voltage is set to VAV2 and the application time is set to TAV2 for the word line WL in the (4n+2)-th (n=0, 1, . . . ) position, the verify voltage is set to VAV3 and the application time is set to TAV3 for the word line WL in the (4n+3)-th (n=0, 1, . . . ) position, and the verify voltage is set to VAV4 and the application time is set to TAV4 for the word line WL in the (4n+4)-th (n=0, 1, . . . ) position, from a given reference position. The values of VAV1 to VAV4 and the values of TAV1 to TAV4 are also determined taking into consideration the dimensions of the word lines WL as described in the fourth and fifth embodiments. That is, when a typically applied verify voltage is VAV0 and the application time is TAV0, VAV1 to VAV4 are set to be lower than VAV0 and TAV1 to TAV4 are set to be smaller than TAV0 in the case where the width dimensions of the word lines WL are larger than the typical value. In contrast, in the case where the width dimensions of the word lines WL are smaller than the typical value, VAV1 to VAV4 are set to be higher than VAV0 and TAV1 to TAV4 are set to be larger than TAV0. However, ΔVAV1, ΔVAV2, ΔVAV3, and ΔVAV4 are all within 10% of the value of VAV0 as described in the fourth embodiment, and ΔTAV1, ΔTAV2, ΔTAV3, and ΔTAV4 are all within 10% of the value of TAV0 as described in the fifth embodiment.

In the above description, for the verify voltages, the example of VAV is described. The same applies to VBV and VCV.

As described in FIG. 26, also regarding the read voltage Vread, the read voltage is set to Vread1 and the application time is set to Tread1 for word line WL in the (4n+1)-th (n=0, 1, . . . ) position, the read voltage is set to Vread2 and the application time is set to Tread2 for the word line WL in the (4n+2)-th (n=0, 1, . . . ) position, the read voltage is set to Vread3 and the application time is set to Tread3 for the word line WL in the (4n+3)-th (n=0, 1, . . . ) position, and the read voltage is set to Vread4 and the application time is set to Tread4 for the word line WL in the (4n+4)-th (n=0, 1, . . . ) position, from a given reference position. The values of Vread1 to Vread4 and the values of Tread1 to Tread4 are also determined taking into consideration the dimensions of the word lines WL as described in the fourth and fifth embodiments. That is, when a typically applied read voltage is Vread0 and the application time is Tread0, Vread1 to Vread4 are set to be lower than Vread0 and Tread1 to Tread4 are set to be smaller than Tread0 in the case where the width dimensions of the word lines WL are larger than the typical value. In contrast, in the case where the width dimensions of the word lines WL are smaller than the typical value, Vpgm1 to Vread4 are set to be higher than Vread0 and Tread1 to Tread4 are set to be larger than Tread0. However, ΔVread1, ΔVread2, ΔVread3, and ΔVread4 are all within 4% of the value of Vread0 as described in the fourth embodiment, and ΔTread1, ΔTread2, ΔTread3, and ΔTread4 are all within 4% of the value of Tread0 as described in the fifth embodiment.

As described in FIG. 27, also regarding the pass voltage Vpass applied to the adjacent word lines WL during a program operation, the pass voltage is set to Vpass1 and the application time is set to Tpass1 for word line WL in the (4n+1)-th (n=0, 1, . . . ) position, the pass voltage is set to Vpass2 and the application time is set to Tpass2 for the word line WL in the (4n+2)-th (n=0, 1, . . . ) position, the pass voltage is set to Vpass3 and the application time is set to Tpass3 for the word line WL in the (4n+3)-th (n=0, 1, . . . ) position, and the pass voltage is set to Vpass4 and the application time is set to Tpass4 for the word line WL in the (4n+4)-th (n=0, 1, . . . ) position, from a given reference position. The values of Vpass1 to Vpass4 and the values of Tpass1 to Tpass4 are also determined taking into consideration the dimensions of the word lines WL as described in the fourth and fifth embodiments. That is, when a typically applied pass voltage is Vpass0 and the application time is Tpass0, Vpass1 to Vpass4 are set to be lower than Vpass0 and Tpass1 to Tpass4 are set to be smaller than Tpass0 in the case where the width dimensions of the word lines WL are larger than the typical value. In contrast, in the case where the width dimensions of the word lines WL are smaller than the typical value, Vpass1 to Vpass4 are set to be higher than Vpass0 and Tpass1 to Tpass4 are set to be larger than Tpass0. However, ΔVpass1, ΔVpass2, ΔVpass3, and ΔVpass4 are all within 5% of the value of Vpass0 as described in the fourth embodiment, and ΔTpass1, ΔTpass2, ΔTpass3, and ΔTpass4 are all within 5% of the value of Tpass0 as described in the fifth embodiment.

According to this embodiment, taking into consideration that the dimension variations due to the double spacer process occur every four lines, the respective program voltages Vpgm, verify voltages VAV, VBV, and VCV, read voltages Vread, and pass voltages Vpass to the word lines WL in the (4n+1)-th, (4n+2)-th, (4n+3)-th, and (4n+4)-th positions from the given reference position and the respective times of application, that is, pulse widths of these voltages are independently changed, so as to reduce the inter-cell variation based on the inter-cell interference effect.

Thus, while in the above-described embodiments a description is given of the case where the widthwise dimensions of the word lines WL are varied as the example, the above-described embodiments are also applicable to the case where the widthwise dimensions of the bit lines BL, the active area AA, and similar member are varied. The above-described embodiments is not applied only to the case where the dimension variations occur every four lines, but can be applied also to the case where the dimension variations occur every two lines or every three lines or the case where the dimension variations occur periodically at intervals exceeding four lines.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell array; and
a control circuit configured to control voltage applied to the memory cell array, wherein
the memory cell array includes:
a plurality of first wiring lines extending in a first direction;
a plurality of second wiring lines extending in a second direction intersecting with the first direction; and
memory cells arranged in respective intersecting portions between the plurality of first wiring lines and the plurality of second wiring lines, and
the control circuit is configured to change voltages applied to the plurality of first wiring lines and/or times during which voltages are applied to the plurality of first wiring lines independently in each of predetermined spatial periods.

2. The nonvolatile semiconductor memory device according to claim 1, wherein
the first wiring lines have substantially identical cross-sectional shapes for each of predetermined spatial periods.

3. The nonvolatile semiconductor memory device according to claim 1, wherein
the plurality of first wiring lines are word lines.

4. The nonvolatile semiconductor memory device according to claim 3, wherein
the control circuit is configured to change respective voltages and/or times during which voltages are applied in the word lines in (4n+1)-th, (4n+2)-th, (4n+3)-th, and (4n+4)-th positions from a given reference position.

5. The nonvolatile semiconductor memory device according to claim 1, wherein
the voltage is at least one of a program voltage Vpgm, a verify voltage Vv, a read voltage Vread, and a pass voltage Vpass.

6. The nonvolatile semiconductor memory device according to claim 1, wherein
the memory cell array includes a NAND cell unit including a plurality of the memory cells series-coupled together, and
the first wiring lines are coupled to control gates of the plurality of memory cells included in the NAND cell unit.

7. An operation method of a nonvolatile semiconductor memory device including a memory cell array, wherein
the memory cell array includes:
a plurality of first wiring lines extending in a first direction;
a plurality of second wiring lines extending in a second direction intersecting with the first direction; and
memory cells arranged in respective intersecting portions between the plurality of first wiring lines and the plurality of second wiring lines, and
the operation method comprises changing voltages applied to the plurality of first wiring lines and/or times during which voltages are applied to the plurality of first wiring lines independently in each of predetermined spatial periods.

8. The operation method of the nonvolatile semiconductor memory device according to claim 7, wherein
the first wiring lines have substantially identical cross-sectional shapes for each of predetermined spatial periods.

9. The operation method of the nonvolatile semiconductor memory device according to claim 7, wherein
the plurality of first wiring lines are word lines.

10. The operation method of the nonvolatile semiconductor memory device according to claim 9, further comprising
changing respective voltages and/or times during which voltages are applied in the word lines in (4n+1)-th, (4n+2)-th, (4n+3)-th, and (4n+4)-th positions from a given reference position.

11. The operation method of the nonvolatile semiconductor memory device according to claim 7, wherein
the voltage is at least one of a program voltage Vpgm, a verify voltage Vv, a read voltage Vread, and a pass voltage Vpass.

12. The operation method of the nonvolatile semiconductor memory device according to claim 7, wherein
the memory cell array includes a NAND cell unit including a plurality of the memory cells series-coupled together, and
the first wiring lines are coupled to control gates of the plurality of memory cells included in the NAND cell unit.
